(19) United States
(12) Patent Application Publication
(10) Pub. No.: US 2022/0365556 A1
(43) Pub. Date: Nov. 17, 2022

(54) SPORTS RETRONIC WEARABLE TERMINAL

(71) Applicant: Clarence Wheeler, Atlanta, GA (US)

(72) Inventor: Clarence Wheeler, Atlanta, GA (US)

(73) Assignee: Sports Retronic, Atlanta, GA (US)

(21) Appl. No.: 17/847,332

(22) Filed: Aug. 2, 2022

Related U.S. Application Data
(63) Continuation-in-part of application No. 15/936,426, filed on Mar. 26, 2018, now Pat. No. 10,824,295.

(51) Int. Cl. G06F 1/16; A44C 5/00; G09F 9/30; G06F 3/041; H05K 1/03; G09G 3/00

(52) U.S. Cl. CPC G06F 1/163; A44C 5/0007; G09F 9/301; G06F 1/1652; G06F 3/0412; H05K 1/0393; G09G 3/035; G06F 2203/04102

(57) ABSTRACT

The present invention discloses an terminal worn by athletes. The terminal comprises an wrist sleeve portion formed of one or more layers, an plurality of input buttons disposed on its exterior surface and an plurality of smartphone and micro-components coupled to the one or more interior layers. The terminal comprises an display assembly disposed on a exterior layer of the wrist sleeve portion exterior surface configured to display one or more objects via an display. The terminal also comprises an flap assembly coupled to the display assembly, the flap assembly comprises an sack portion which hold an play-card or similar object and a pull-tab which allocates an user to separate the flap assembly from the display assembly. The current invention also discloses a method for determining an location of a object and executing an function of the object based upon an user interaction. The method consisting of moving an object from a first location to a second location and a input circuitry determining a row signal strength and a processor executing the object function on a second user interface based upon a second obtained signal strength.

### BACKGROUND OF THE INVENTION

### Field of the Invention

The invention generally relates to the field of terminals and touch panels for the terminal.

### BRIEF SUMMARY OF THE PRESENT INVENTION AND ADVANTAGES

The present invention comprises the field of terminals. The terminal may be formed of an fabric material (e.g., such as microfiber and cotton), rubber and silicone that may allocate the wearable terminal to stretch and adapt to fit many different wrist shape and sizes without the need for complex adjustments. The terminal may be worn like a watch, wristband, sweatband or similar object around the wrist or arm of a user. The terminal comprises an flexible display assembly made of one or more flexible layer and an wrist sleeve portion made up of one or more layers.

The terminal may comprise one or more flexible printed-circuit intergraded within the wrist sleeve portion that may comprise one or more electrical components populated onto its surface that may allocate wireless communication with an external device, and input and output interaction with the user of the terminal. Specifically, the one or more flexible printed circuits may contain several micro smart-phone components, WIFI and Bluetooth chipset, an micro processor, one or more sensors, intended to power the terminal and its components. The present inventions also discloses an system and method for determining an location of an object and executing an function of the object based upon an user interaction with the object of the terminal touch panel.

### BRIEF DESCRIPTION OF THE SEVERAL VIEWS OF THE DRAWINGS

FIG. 1 is a shape diagram for describing a one or more electrical components populated onto one or more printed circuit films within the terminal.

FIG. 2 is a perspective view, illustrating the terminal according to one embodiment of the present invention.

FIG. 3A is an cross-sectional view of the wrist sleeve portion according to one embodiment.

FIG. 3B is an cross-sectional view of the wrist sleeve portion broken away shown the multiple layer according to one embodiment.

FIG. 3C is an cross-sectional view schematically illustrating the wrist sleeve portion according to another embodiment.

FIG. 3D is an cross-sectional view schematically illustrating the multi-layer associated with the wrist sleeve portion according to another embodiment.

FIG. 4A is an schematic diagram of the flexible display assembly.

FIG. 4B is an exploded view of the one or more components of the flexible display assembly.

FIGS. 4C & 4D is an illustration of an schematic diagram of the flexible display assembly stacked layers.

FIGS. 4E & 4F are cross-sectional views of the one or more stacked layers relatively to the flexible display assembly.

FIG. 5A illustrates the wrist sleeve portion in relations with the one or more cutout (CO).

FIG. 5B illustrates the wrist sleeve portion in relations with the one or more means for securing to the wrist of an user.

FIG. 6 is an illustration of the wrist sleeve portion in conjunction with one or more electrical components integrated within the wrist sleeve portion.

FIG. 7A is an rear perspective view of the flexible keymat.

FIG. 7B is an front perspective view of the flexible keymat.

FIG. 7C is an cross-view perspective of the flexible keymat disposed on the one or more integrated layers of the wrist sleeve portion.

FIG. 7D is an top view perspective of the key top.

FIG. 7E is an bottom view perspective of the key top.

FIG. 7F is an illustration of the one or more key tops disposed on the wrist sleeve portion.

FIG. 7G is an cross-sectional view of one or more additional components disposed on the exterior layer of the wrist sleeve portion.

FIG. 7H is an cross-sectional view of one or more additional components integrated within the wrist sleeve portion.

FIG. 8A is an perspective view of the terminal having an flexible display assembly and an respective flap assembly.

FIG. 8B is an illustration of the flexible plastic sack.

FIG. 8C is an cross-sectional view of the flexible plastic sack disposed within the flap assembly.

FIG. 8D is an cross-sectional view illustrating the flexible display assembly in relations to the flap assembly.

FIG. 8E is an cross-sectional view illustrating the pull-tab in relations to the flap assembly.

FIG. 9 is an illustration showing one embodiment of an touch panel sensor system.

FIG. 10 is an illustration showing another embodiment of the touch panel sensor system.

FIG. 11 is an exemplary illustration of the touch panel sensor.

FIGS. 12a-12c are illustrations showing an external object disposed over the touch panel.

FIG. 13 is an conceptual view showing an embodiment(s) of one or more object(s) disposed within an respective subset of row(s) and column(s).

FIG. 14 is an method for executing an function of the system according to an embodiment of the present invention.

FIG. 15-17 are illustrations of the method for FIG. 14 according to an embodiment of the present invention.

### DETAILED DESCRIPTION OF THE INVENTION

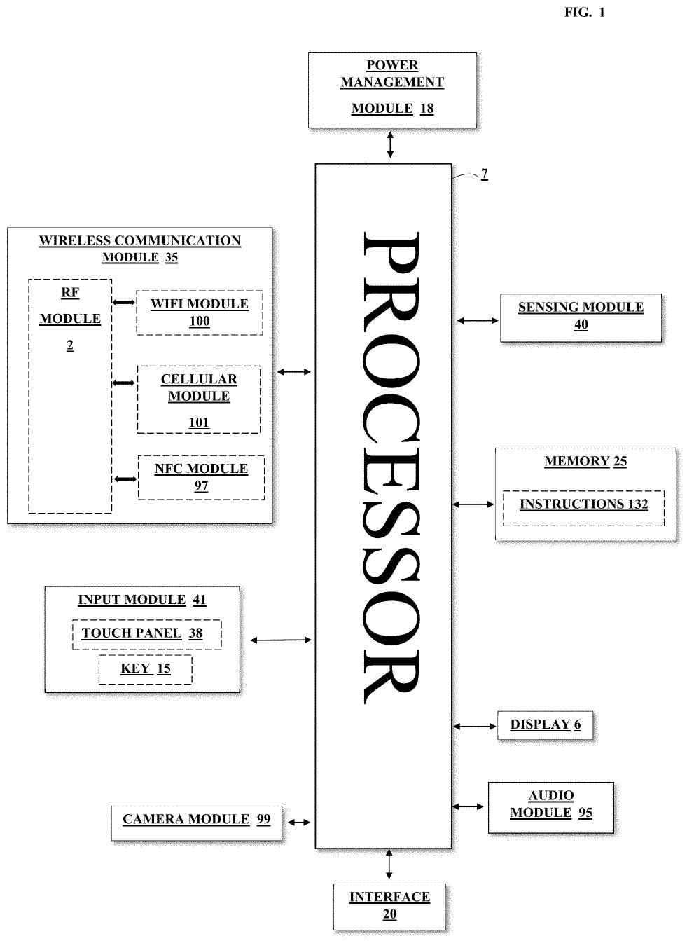

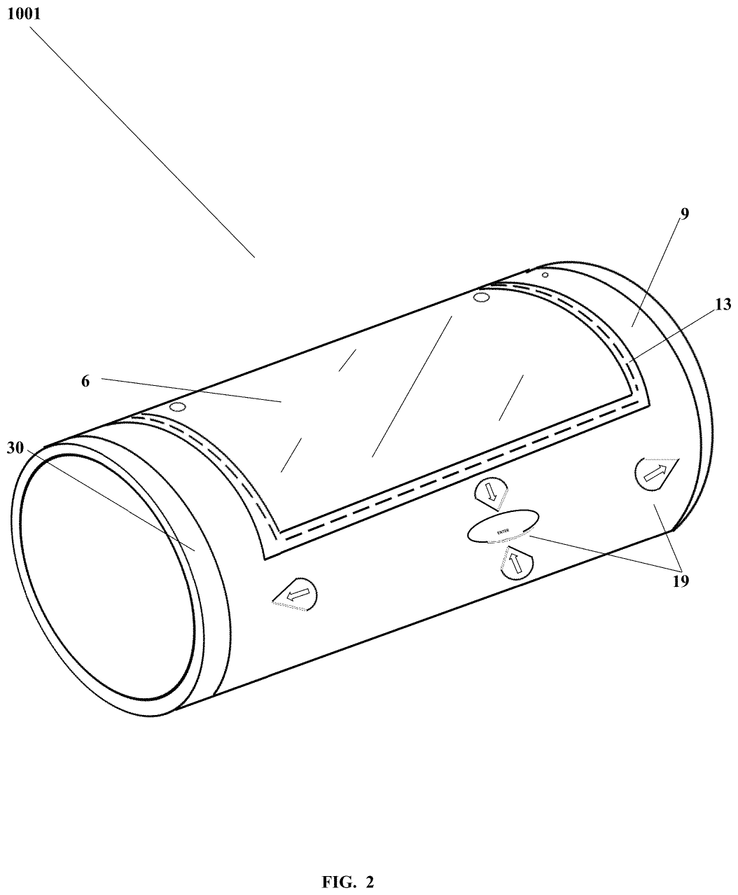

FIG. 1 is an block diagram describing components that may be coupled to the one or more flexible printed circuits of the terminal 1001. Furthermore, terminal 1001 may include one or more processor 7 which may control a multitude of hardware or software components that may be connected thereon and may also perform various data processing and operations by executing an operating system, application program, or operating system and application instructions. The processor 7 may be implemented with a system on chip (SoC). The processor 7 may further include a graphic processing unit (GPU) and/or an image signal processor. For example, processor 7 duties may be to load commands or data received from one or more components and process them and store various data in a nonvolatile memory. During operation, the processor 7 executes one or more programs stored within the memory 25 and controls the general operation of the program instructions.

The wireless communication module 35 comprises an RF module 2, WIFI module 100, cellular module 101, and an NFC module 97. The wireless communication module 35 allows wireless communication which may enable the remote interaction between terminal 1001 and an external device and or via internet, which may include communication systems as PAN (Personal Area Network), NFC (Near Field Communication), Zigbee, Bluetooth, RFID (Radio Frequency Identification), IrDA, (Infrared Data Association), LAN (Local Area Network), WIFI, MAN (Metropolitan Area Network) WiMAX (World Interoperability for Microwave Access), HSDPA (High Speed Downlink Packet Access), WAN (Wide Area Network), Wibro (Wireless Broadband), UWB (Ultra-Wideband), LMDS (Local Multiple Distribution Service), IPV6 (Internet Protocol Version 6), and RF (Radio Frequency) communication systems. The wireless communication module 35 may include a processor for processing data transmitted/received through a corresponding module and or may be included in one integrated chip (IC) or IC package.

The RF module 2, for example, may be used to transmit/receive communication signals.

The RF module 2 may include a transceiver, a power amp module (PAM), a frequency filter, a low noise amplifier (LNA), or an antenna.

The cellular module 101, for example, may allocate voice call, video call, text service, or internet service through an communication network. The cellular module 101 may perform a distinction and authentication operation in a communication network by using an SIM card or virtual SIM card. The WiFi module 100, and NFC module 97 may include a processor for processing data transmitted/received through a corresponding module. The present disclosure, at least part (e.g., at least one) of the cellular module 101, the WiFi module 100 and NFC module 97 may be included in one integrated chip (IC) or IC package. At least one of the cellular module 101, the WiFi module 100 and the NFC module 97 may transmit/receive RF signals through a separate RF module.

The terminal 1001 may include an memory 25, an internal memory that may comprise a SSD (Solid State Drive), NAS (Network Attached Storage), Dual-Channel RAM (Random Access Memory), Multi-ROM (Read-Only Memory), Flash Memory (Flash Memory Type), Hard Disk (Hard Disk Type), Multimedia Card Micro (Multimedia Card Micro Type), SRAM (Static Random Access Memory), EEPROM (Electrically Erasable Programmable Read-Only Memory), PROM (Programmable Read-Only Memory), may further include a card type memory Compact Flash (CF), Secure Digital (SD), Micro Micro-SD, Mini-SD, Extreme Digital (xD), Multimedia Card (MMC) or a memory stick. The memory 25 may store the operating system components, application data, graphics and critical system files, many of the previously mentioned files and systems may be separated to different storage chips throughout flexible printed circuit-board.

The memory 25 also stores one or more instructions 131 for executing of rearranging the icon layout on the display 6 and instructions 132 for generating a object opening execution region 314 in response to a user first action with one or more objects 1009 on the display 6.

The terminal 1001 may include a power management module 18 that may be an off-chip ex. (module) or on-chip, duties to manage the power of the terminal 1001. The power management module 18 may include a power management IC (PMIC), a charger IC, or a battery gauge, for example. The PMIC may have a wired and/or wireless charging capabilities.

In order to implement the wireless charging function the terminal 1001 may comprise one or more coils that may obtain one or more power control signals via an external apparatus via an NFC function, the one or more coils may be connected to one or more communication processor and a charge Integrated Circuit (IC), respectively. An NFC IC or a Wireless Charger (WC) IC may be on a connection of the one or more coils to a circuit of the terminal 1001. These ICs control current and Voltage during charging operations. Alternatively, the terminal 1001 may obtain an wireless power via the one or more antennas via an radio-frequency signals from an external apparatus and harvest wireless power from the radio-frequency signals using one or more rectifiers circuitry.

The terminal 1001 may include one or more input module 41 which may be composed of one or more key(s) 15 and an touch panel 38 (static pressure/electrostatic), the touch panel 38 may use at least one of capacitive, resistive, infrared, or ultrasonic method, for example.

Additionally, the touch panel 38 may further include a control circuit, alternatively the touch panel 38 may further include a tactile layer to provide tactile response to a user. The key 15 may include a physical button, an optical key, or a keypad.

Sensing module 40 may measure physical quantities or detect an operating state of terminal 1001, thereby converting the measured or detected information into electrical signals, and may accommodate many different sensors (ex. gesture sensor, gyro sensor, barometric sensor, magnetic sensor, acceleration sensor, grip sensor, proximity sensor, temperature/humidity sensor, illumination sensor, infrared (IR) sensor. The sensing module 40 may further include a control circuit which may control at least one sensor therein and an additional processor to control the sensing module 40 while the main processor may be in a sleep or consumption state.

The display 6 may be an LCD (Liquid Crystal Display), a thin film TLCD (Transistor-Liquid Crystal Display), OLED (Organic Light-Emitting Diode), a Flexible Display, 3-D Display (may include at least one of 3D displays) and may incorporate a touch sensor. Some of these displays may be configured to be transparent to view the outside through them. This may be called a transparent display, for example a transparent display and the like (Transparent Organic Light Emitting Diode) TOLED.

The display 6 according to the implementation of terminal 1001 may also be two or more. For example, it may be provided in the terminal 1001 at the same time the external display module (not illustrated) and an internal display module (not illustrated). The touch panel 38 may be configured to detect even a touch input as well as the position and area of the touch input pressure. The interface 20 may include a high-definition multimedia interface (HDMI), a universal serial bus (USB), an optical interface, or a D-subminiature (sub). Alternatively, the interface 20 may include a mobile high definition link (MHL) interface, secure digital (SD) card/multi-media card (MMC) interface, or an infrared data association (IrDA) standard interface.

The interface 20 may include an high-definition multimedia interface (HDMI), a universal serial bus (USB), an optical interface, or a D-subminiature (sub). The interface 20 may be included in the communication interface. Additionally or alternatively, the interface 20 may include a mobile high definition link (MHL) interface, a secure Digital (SD) card/multi-media card (MMC) interface, or an infrared data association (IrDA) standard interface.

The audio module 95 may convert sound into electrical signals and convert electrical signals into sounds. At least some components of the audio module 95 may be included in the input/output interface. The audio module 95 processes sound information inputted/outputted through a speaker, a receiver, an earphone, or a microphone.

The camera module 99, which captures still images and video, may include at least one image sensor (e.g., a front sensor or a rear sensor), a lens, an image signal processor (ISP), or a flash (for example, an LED or a xenon lamp).

Referring to FIG. 2 describes the terminal 1001, the terminal 1001 comprises an wrist sleeve portion 9 and an display assembly 13. The wrist-sleeve portion 9 comprises an planar body inclosing the wrist and forearm area of an user, the wrist sleeve portion 9 may be formed of an suitable material which allocates flexibility as well as strength. For instance, suitable materials may be nylon, polyester, cotton fabric, leather, plastic or a combination thereof.

Additionally, suitable materials may be one or more fabrics and/or materials formed from polymer, metal, glass, graphite, ceramic, natural materials such as bamboo, or other organic and inorganic materials or an combination of the two. The fabrics and/or materials may be made of single filament stands (e.g., micro-fibers), may be yarns or other strands formed by intertwining multiple filaments of materials together.

Monofilaments formed from polymer cores with metal coatings and monofilaments formed from three or more layers may also be used. The wrist sleeve portion 9 may comprise one or more additional layers integrated intermediate its exterior layer 47 and interior layer 14 configured to add additional protection, durability and allocate one or more electrical components and/or circuits to integrate within the wrist sleeve portion 9. Further, the wrist sleeve portion 9 comprises an respective cuff edge 30 at opposing sides prolonging around the user's wrist and forearm region. For, instance the cuff edge 30 may be made of an different material as the wrist sleeve portion 9 and the cuff edge 30 region may be intergraded with an elastic material.

The terminal 1001 comprises an plurality of keytops 19 disposed on its surface envisioned to allocate the user to navigate one or more settings or execute one or more action on the one or more programs such as selecting and viewing multimedia file or powering on and off the apparatus.

The terminal 1001 may comprise an means for securing the wrist sleeve portion 9 to an user wrist via respective attachment strips 46 that may be coupled to an predetermine lower region of wrist sleeve portion 9 exterior layer 47. The attachment strips 46 may be formed of the same materials as the wrist sleeve portion 9. Alternatively, the attachment strips 46 may be formed of an suitable strong and flexible material, such as nylon, or an inelastic material. The attachment strips 46 inner surface comprises an complementary hook or loop material such as that sold under the trademark VELCRO®. The attachment strips 46 length may be sufficient so that when the front region is pulled towards the backside region inclosing around the user wrist and/or forearm the attachment strips 46 comprises adequate length to mate with the velcro pad(s) 27 disposed at the rear side region with minimal tension.

The display assembly 13 may comprise one or more layers that allocates support and for the display layer 6. The display assembly 13 form an quadrilateral-shape comprising an center opening 10 constituting an window structure may of an suitable material which allocates flexibility as well as strength. Suitable materials may be made of an thin flexible plastic or rubber material or an combination thereof. For example, one or more layers of an light weight flexible plastic or rubber material such as thermoplastic, ethylene vinyl acetate (EVA), Kraton styrene polymer, PVC, ENGAGE, or an polyethylene polymer may be laminated, printed, or molded to form the display assembly 13 into an suitable thickness.

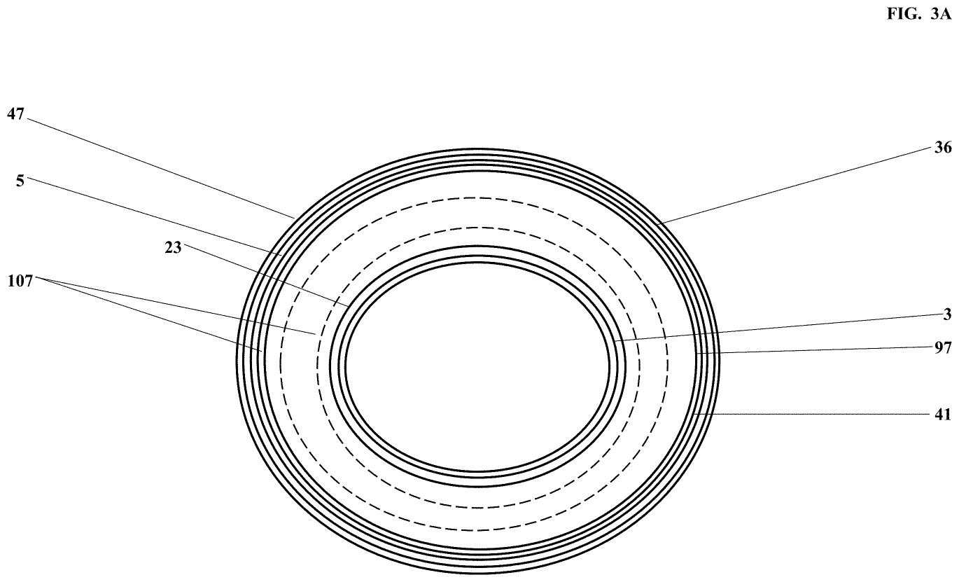

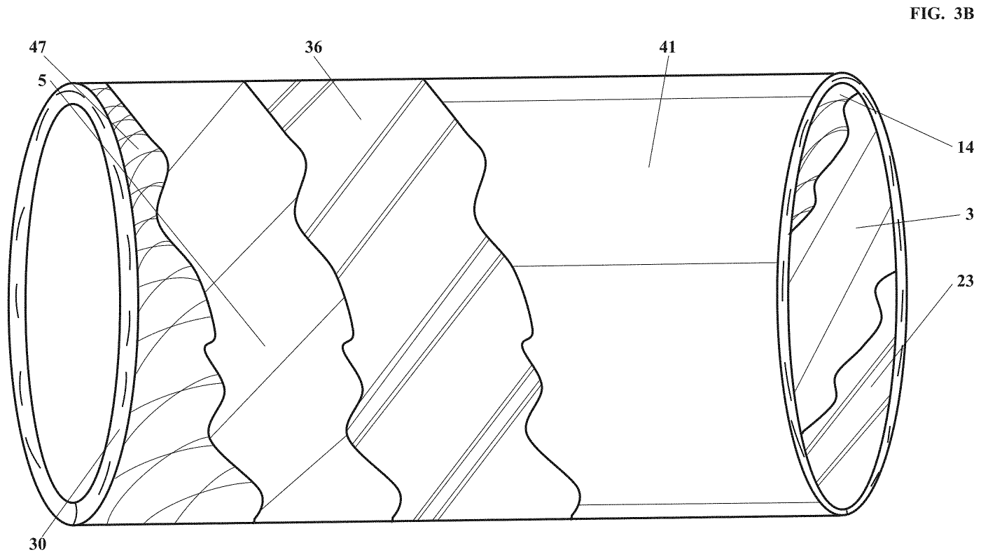

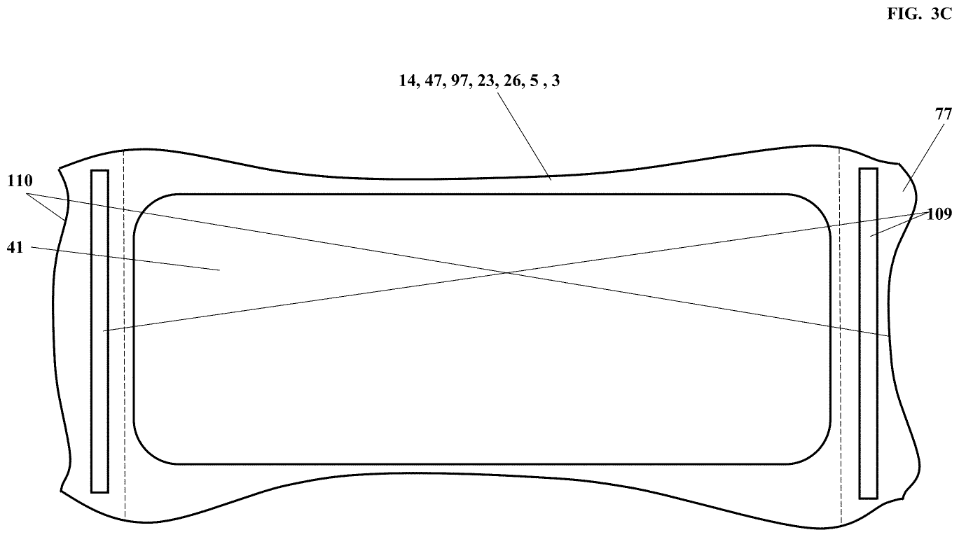

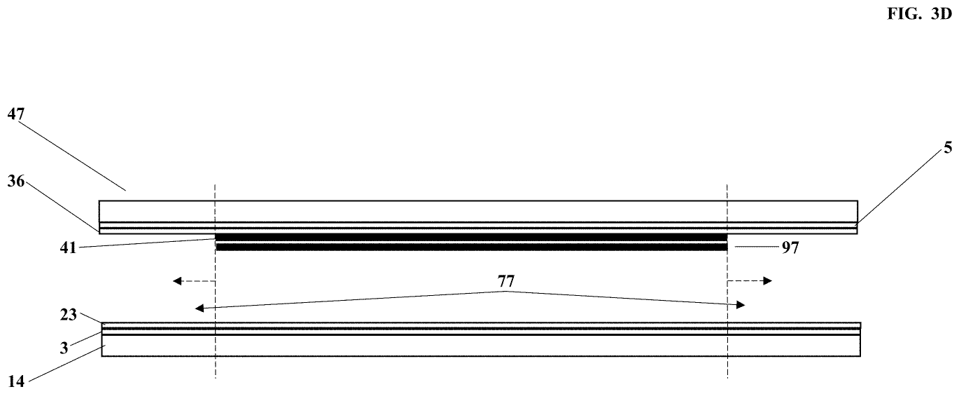

FIG. 3A is an cross-sectional view of the wrist sleeve portion 9 according to one embodiment, FIG. 3B is an cross-sectional view of the wrist sleeve portion 9 broken away shown the multiple layer according to one embodiment.

FIG. 3C is an cross-sectional view schematically illustrating the wrist sleeve portion 9 according to another embodiment. FIG. 3D is an cross-sectional view schematically illustrating the wrist sleeve portion 9 multiple layer according to another embodiment.

According to the present embodiment, the wrist sleeve portion 9 comprises an exterior layer 47 superimposing the interior layer 14 forming an multi-layer film. The exterior layer 47 comprise an intermediate layer 5 and inner layer 36. The exterior layer 47 is formed from of a suitable material such a woven or non/woven fabrics made of natural and/or synthetic fibers or a flexible plastic material. The exterior layer 47 comprises any suitable thickness in the range of 0.5 mm and up. The intermediate layer 5 is formed of an liquid absorbent and containing material such as cellulose, preferably viscose rayon, a synthetic shammy material. The intermediate layer 5 comprises any suitable thickness in the range of 0.3 mm and up. The inner layer 36 is formed of an flexible rubber material. The inner layer 36 disposed on the intermediate layer 5 may be used for permanently restricting liquid substances from penetrating the structuring layer 41 and electrical components disposed on the structuring layer 41. The inner layer 36 comprises any suitable thickness in the range of 0.2 mm and up. To form the multi-layer exterior layer 47, the exterior layer 47 properties can be efficiently co-extruded forming an multi-layer film, which can then be micro-fibrillated to produce a microfiber article having a desired combination of properties based on the composition and properties of the different layers of the co-extruded film. Alternatively, the exterior layer 47 may be prepared by forming an respective exterior layer 47, intermediate layer 5 and inner layer 36 and laminating or adhesion the layers to one another to form an multi-layer film.

Further, included is an interior layer 14 comprising an outer surface in contact with the wrist of an user, an inner layer 23 disposed on the interior layer 14 surface at an non-contact position on the user wrist and an intermediate layer 3 disposed on the inner layer surface at an non-contact position with the user wrist forming an multi-layer film. The interior layer 14 may also be formed from a suitable material such as a woven or non/woven fabrics made of natural and/or synthetic fibers or a flexible plastic material. The interior layer 14 comprises any suitable thickness in the range of 0.5 mm and up. The intermediate layer 3 is formed of an liquid absorbent and containing material such as cellulose, preferably viscose rayon, a synthetic shammy material.

The intermediate layer 3 comprises any suitable thickness in the range of 0.3 mm and up. The inner layer 23 is formed of an flexible rubber material. The inner layer 23 disposed on the intermediate layer 3 may be used for permanently restricting liquid substances from penetrating the structuring layer 41 and electrical components disposed on the structuring layer 41 from the inner wrist region. The inner layer 23 comprises any suitable thickness in the range of 0.2 mm and up. To form the multi-layer interior layer 14, the interior layer 14 properties can be efficiently co-extruded forming an multi-layer film, which can then be micro-fibrillated to produce a microfiber article having a desired combination of properties based on the composition and properties of the different layers of the co-extruded film. Alternatively, the interior layer 14 may be prepared by forming an respective interior layer 14, intermediate layer 3 and inner layer 23 and laminating or adhesion the layers to one another to form an multi-layer film.

Further, disposed on the interior layer 14 intermediate layer top surface or exterior layer 47 intermediate layer bottom surface is an respective flexible structuring layer 41 adapted to house one or more electrical components on its surface. To do this the structuring layer 41 comprises one or more adhesive layers made of an thermoplastic material having an low melting point disposed on its top surface, which allocates the first and second flexible printed circuits (34, 72) to be laminated or thermally adhered to the structing layer 41 top surface and one or more electrical components to be disposed on its top surface. The structuring layer 41 may be coupled to the intermediate layer by one or more adhesive bonds on lamination processes. The structing layer 41 is made of an flexible rubber material. The structuring layer 3 comprises any suitable thickness in the range of 0.3 mm and up. The structuring layer 41 may also comprise an thin adhesive cover layer disposed on its top surface providing an extra protective cover for the one or more printed circuit films and/or electrical components populated onto the printed circuit films made of an polypropylene, polyethylene terephthalate, polyamide polyimide or other suitable materials or an combination thereof. The structuring layer 41 comprises an thickness in the range of 0.3 mm and up.

In addition, disposed on the bottom surface of the structuring layer 41 of the exterior layer 47 is an respective flexible power source structuring layer 97 adapted to house one or more power sources (ex., rechargeable battery, printed battery or super capacitors). The power source structuring layer 97 can be structured as an flat surface having an partial recess for housing the one or more power sources. Also to do this the power source structuring layer 97 comprises one or more adhesive layers made of an thermoplastic material having an low melting point disposed on its top surface, which allocates the one or more printed batteries to be laminated or thermally adhered to the power source structing layer 97. The power source structuring layer 97 may be coupled to the bottom surface of the structuring layer 41 by one or more adhesive bonds on lamination processes. The power source structing layer 97 can be made of an flexible rubber material. The power source structuring layer 97 comprises any suitable thickness in the range of 0.3 mm and up.

Moreover, in process of sandwiching the respective interior layer 14, exterior layer 41 and structuring layer 47 together the distal edges of each layer are stitched together forming an single panel and the distal edges 110 of the single panel edges are cuffed inward and stitched constituting cuffed edges 30.

Specifically, upon sandwiching the inner layer 23, 36, intermediate layer 5, 3 and structuring layer 41 to the exterior layer 47 and interior layer 14 the exterior layer 47 and interior layer 14 comprises in the range of 3 mm and up of excess layer 77 surrounding the structuring layer 41 which allocates an elastic strip 109 to be disposed adjacent the panel distal edges 110 without overlapping the structuring layer 41 wherein the panel distal edges 110 are cuffed inward stitching the elastic strip 109 within the cuffed edges 30 constituting an stretchable edge region FIGS. 3C & 3D.

However, the plurality of layers of the wrist sleeve portion 9 in reference to FIGS. 3A-3D, the one or more layers of the wrist sleeve portion 9 can be coupled together to form a multi-film layer by a lamination, co-extrusion or adhesive process. For example, the one or more layers of the wrist sleeve portion 9 may be coupled together by a co-extrusion process, the wrist sleeve portion 9 may comprise a exterior layer 47 and interior layer 14 having the same property's (e.g., plastic material or woven or non-woven microfiber material), a non-microfiber inner layer 36 and inner layer 23 having the same property's (e.g., flexible rubber material) and a structuring layer 41 intermediate the inner layers (36, 23) having similar property's of the inner layers (36, 23). Further, the properties of the one or more layers can combine to produce a flexible rubber or elastomeric cloth-like article with a microfiber surface that might independently be hydrophobic, hydrophilic, oleophobic, oleophilic, etc. Or, the different layers may be chosen to have different microfiber surface properties, or preferred mechanical properties. The one or more layers may be transformed into a single article (e.g., wrist sleeve portion 9) using standard methods of micro fibrillation, including hydroentanglement techniques using a hydrogen tangling machine. The one or more layers of the multi-layer film, and different amounts or thicknesses of the one or more layers, may be microfibrillated to form microfibers.

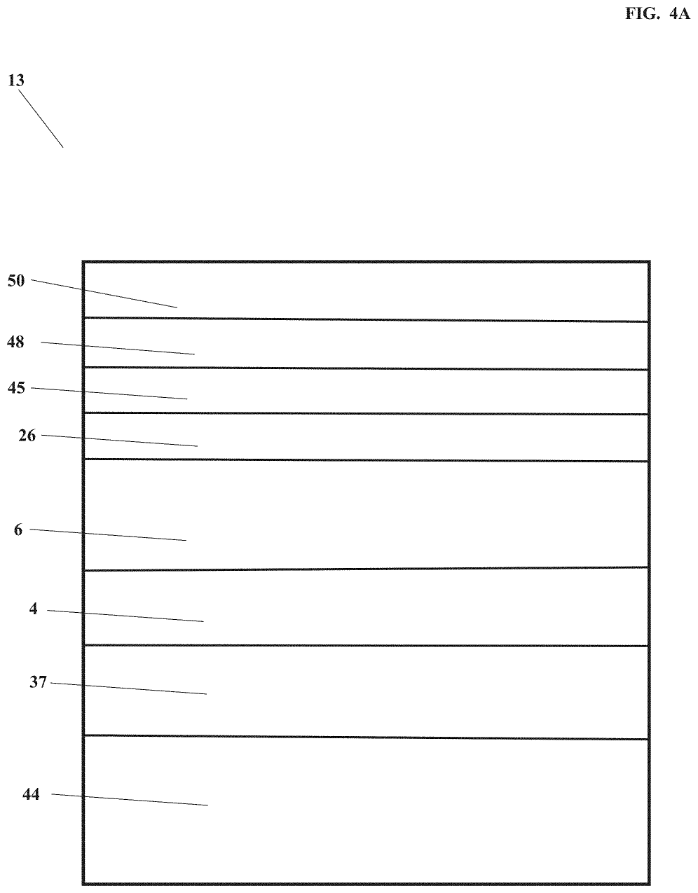

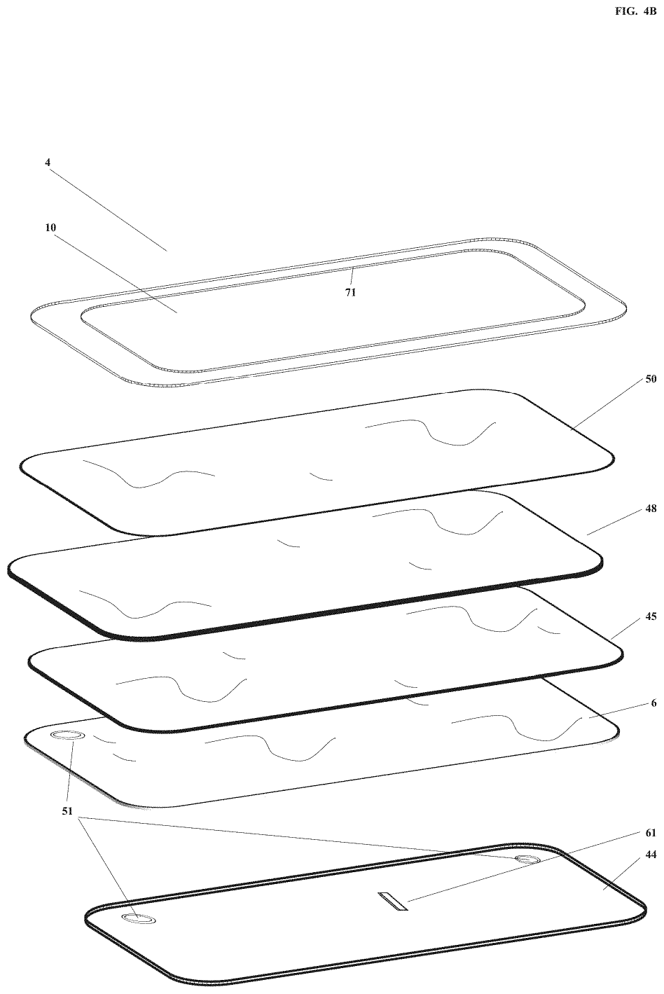

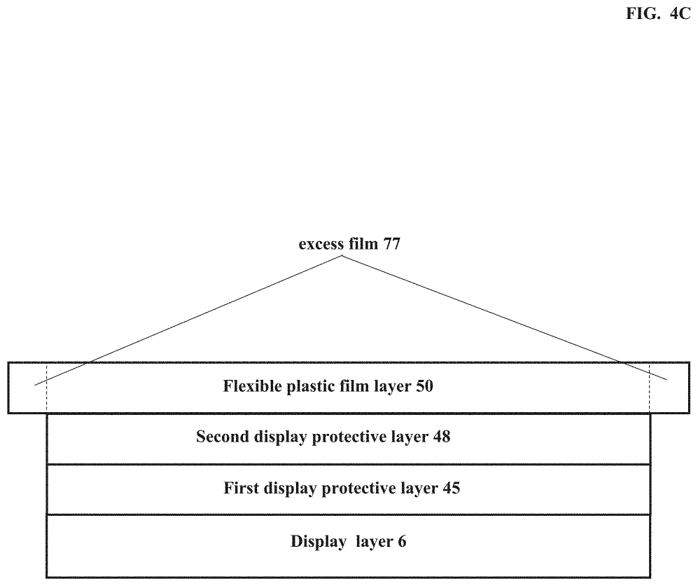

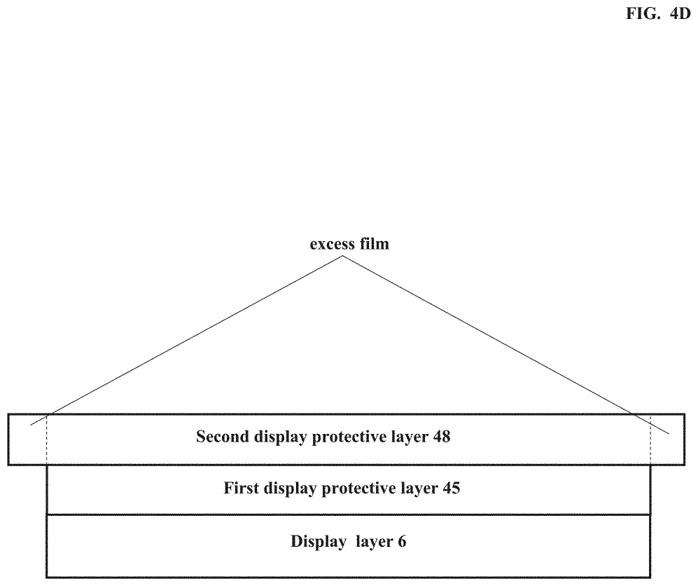

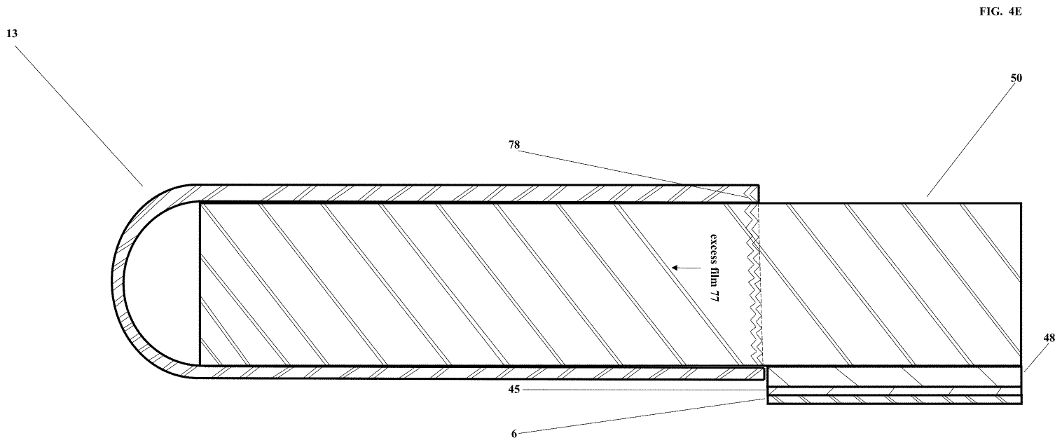

Referring to FIG. 4A, is an schematic diagram of the flexible display assembly 13 having an plurality of respective stacked layers. While FIG. 4B is an exploded view of the flexible display assembly 13. FIG. 4C and FIG. 4D is an illustration of an schematic diagram of the one or more flexible display assembly 13 stacked layers. FIGS. 4E & 4F are cross-sectional views of the one or more stacked layers disposed within the flexible display assembly 13.

The flexible display assembly 13 is further disposed on the exterior layer 47 surface at the display region (DR) via one or more coupling processes (e.g., adhesive bonding, stitching or an combination thereof), and further configured to display an image and/or video on the display 6 upon obtaining data (e.g., multimedia message and etc.) from an external apparatus (e.g., such as an notebook or desktop computer) via an wireless communication network.

Further, the wrist sleeve portion 9 comprises an flexible display assembly 13 having an flexible window housing 4, display 6, first display protective layer 45, second display protective layer 48 and an rear cover layer 44.

The display 6 a flexible organic light-emitting diode (OLED), light-emitting diode (LED) or liquid crystal display (LCD) is disposed within the flexible window housing 4 center opening 10. The display 6 is further configured to display an image and/or video on the display 6 upon obtaining data (e.g., playbook information) from an external apparatus (e.g., such as an notebook or desktop computer) via an wireless communication network. In addition, the display 6 may also include one or more touch-sensitive elements configured to detect an user's touch at predetermine regions on the flexible display assembly 13 and to generate electrical signals in response to the detected touch. In addition, the display 6 comprises two spherical-shape cutouts 51 at opposing upper regions of its surface. The spherical-shape cutouts 51 are further positioned to allocate one or more sensor lens (e.g., light emitting elements and proximity sensors) to arrange within the spherical-shape cutouts 51.

The plastic film layer may be to protect the display 6 front surface. The flexible window housing 4 can be made of an silicone rubber, leather or flexible plastic material.

In the present embodiment, the display 6 is disposed on the first display protective layer 45 via an optically clear adhesive (OCA) layer 26. To do this the optically clear adhesive layer 26 is applied to the bottom surface of the first display protective layer 45 and the display 6 may be applied to the bottom surface of the first display protective layer 45.

The first display protective layer 45 is made of an thin flexible transparent material, comprising any suitable thickness of in the range of 0.1 mm and up.

Further, the first display protective layer 45 can be coupled to the second display protective layer 48 via an optically clear adhesive layer 26, where the optically clear layer 26 is applied to the rear surface of the second display protective layer 48 or front surface of the first display protective layer 45. The second display protective layer 48 is made of an thin flexible transparent material, comprising any suitable thickness in the range of 0.05 mm. Otherwise, the first display protective layer 45 rear region may comprise an adhesive surface which allocates coupling the display 6 to its surface.

The first display protective layer 45 and second display protective layer 48 may be coupled to the display 6 to protect the front surface of the display 6 from scratches, cracks and liquid substances. In general, different adjacent discrete layers of the display assembly 13 may be joined by an adhesive material between the adjacent materials. Adhesive material between an optical path from the display emitters of the display 6 and user's eye are OCA.

Further, the display 6 comprising the first and second display protective layers 48, 45 is coupled to the flexible window housing 4 in or more ways. In the first instance, an flexible plastic film layer 50 is coupled to the second display protective layer 48 via an thin optically clear adhesive layer 26, where the optically clear adhesive layer 26 is applied to the rear surface of the flexible plastic film layer 50. The flexible plastic film layer 50 is made of an thin flexible plastic transparent material, comprising any suitable thickness of approximately 0.05 mm and up. The flexible plastic film layer 50 may be to protect the first display protective layer 45, second display protective layer 48 and display 6 front surface from further damages.

The display 6 comprising the first and second display protective layers 48, 45 and flexible plastic film layer 50 is coupled within the flexible window housing 4 via an stitching and adhesive process. Specifically, the flexible window housing 4 forms an reedy quadrilateral-shape with outer edges that partially curve. The flexible window housing 4 comprises an center opening 10 that prolongs outwardly leaving approximately 11.43 mm and up of the flexible window housing 4 constituting an window (e.g., center opening). To couple the display 6 to the flexible window housing 4 the flexible window housing 4 inner lips 70 are partially bifurcated to allocate the flexible plastic film layer 50 excess film 77 (begins at dashed lines) to be inserted within the inner lips 70, an small amount of adhesive may be applied to the inner surface of the inner lips 70, the flexible plastic film layer 50 excess film 77 is then disposed within the inner lips 70 and the flexible window housing 4 is stitched 78 at one or more regions near its boarding (e.g., outer edges and an opposing predetermine region) coupling the flexible plastic film layer 50 to the flexible window housing 4. However, upon coupling the second display protective layer 48 to the flexible plastic film layer 50, the flexible plastic film layer 50 comprises in the range of 3 mm and up of excess film 77 boarding the second display protective layer 48, first display protective layer 45 and display 6 this allocate the flexible plastic film layer 50 to be disposed within the flexible window housing 4 inner lips 70 without damaging the first and second display protective layer 48, 45 and display layer 6 FIGS. 4C & 4E.

Alternatively, the display 6 comprising the first and second display protective layer 48, 45 is directly coupled to the flexible window housing 4 without the intervene of an flexible plastic film layer 50. To do this, an small amount of adhesive is disposed within the flexible window housing 4 inner lips 70, the second display protective display layer 48 excess film 77 (begins at dashed lines) is disposed within the flexible window housing 4 inner lips 70 and the flexible window housing 4 is stitched 78 at one or more regions near its boarding (e.g., outer edges and an opposing predetermine region) coupling the second display protective layer 48 within the flexible window housing 4. Specifically, upon coupling the second display protective layer 48 to the first display protective layer 45 and display layer 6 the second display protective layer 48 comprises in the range of 3 mm and up of excess film 77 boarding the first display protective layer 45 and display layer 6 this allocate the second display protective layer 45 to be disposed within the flexible window housing 4 inner lips 70 without damaging the first display protective layer 45 and display layer 6 FIGS. 4D & 4F.

The flexible plastic film layer 50 is made of an thin flexible plastic transparent material, comprising any suitable thickness in the range of 0.05 mm and up. The flexible plastic film layer 50 may be to protect the first display protective layer 45, second display protective layer 48 and display 6 front surface from further damages.

The flexible window housing 4 is made of an silicone rubber, leather or flexible plastic material. The flexible window housing 4 comprises any suitable thickness in the range of 1.27 mm and up. For instance, one or more layers of rubber, leather, gel or plastic material may be laminated, bonded or 3D-printed together to form the flexible window layer 4.

In some implementations, the rear cover/support structure 44 is disposed on the rear surface of the flexible window housing 4 via an adhesive layer 37. In some implementations, the rear cover/support structure 44 may be bonded to the rear surface of the flexible window housing 4 via an adhesive. Further, the rear cover/support structure 44 forms an reedy quadrilateral-shape layer with outer edges the partially curve, also corresponding with the dimensions of the flexible window housing 4. Specifically, the rear cover/support structure 44 is formed of an flexible rubber material having an heavier density than the flexible window housing 4. This higher density level may limit over bending of the display assembly 13, for instance the flexible window housing 4 may comprises an density in the range of 0.001 kg to 0.01 kg and the rear cover/support structure 44 may comprise an density in the range of 0.005 kg to 0.02 kg.

The rear cover/support structure 44 is further made of an flexible rubber material. The rear cover/support structure 44 comprises an thickness of approximately 3.35 mm and up. The rear cover/support structure 44 further comprises two spherical-shape cutouts 51 at opposing upper regions of its surface and one or more incisions 62 disposed at an predetermine region below the two spherical-shape cutouts 51. The spherical-shape cutouts 51 are further positioned to allocate one or more sensor lens (e.g., light emitting elements and proximity sensors) to arrange within the spherical-shape cutouts 51.

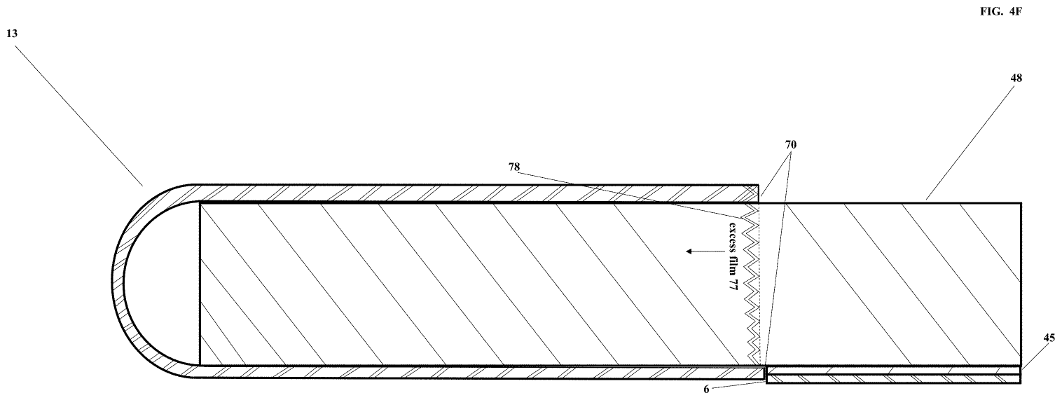

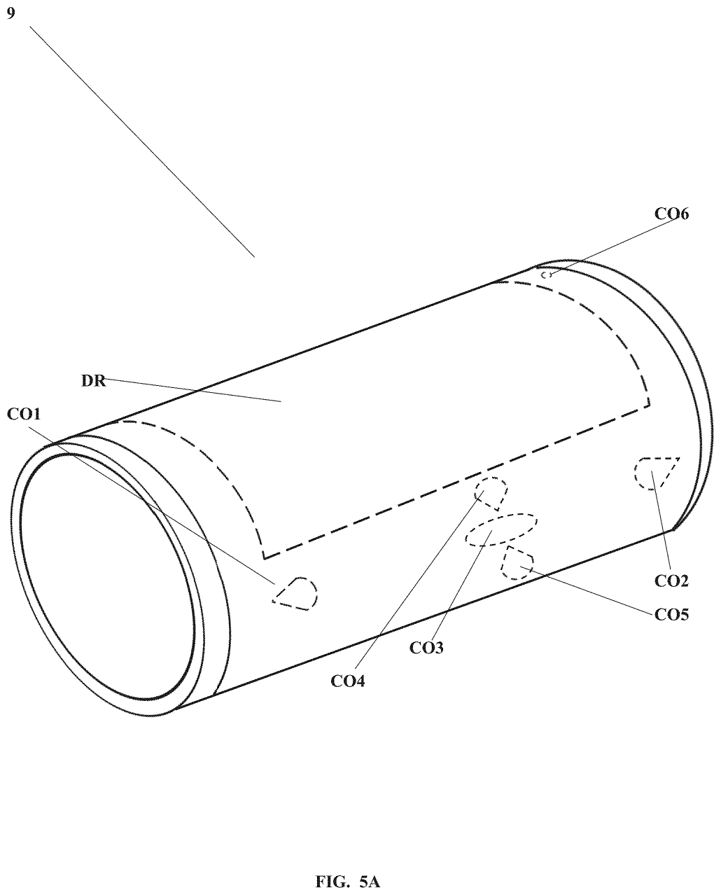

However, the one or more incision 62 may be formed to allocate the display 6 and one or more power sources ribbon to deviate the rear cover/support structure 44 and introduce into the wrist sleeve portion 9 incision 62 to couple to the one or more flexible printed circuits. FIG. 5A illustrates the wrist sleeve portion 9 in relations with the one or more cutout (CO) indicated as dashed-lines. FIG. 5B illustrates the wrist sleeve portion 9 in relations with the one or more means for securing to the wrist of an user. As mentioned above in FIG. 3A-3E the wrist sleeve portion 9 comprises an interior layer 14 comprising an intermediate layer 5 and inner layer 23. An exterior layer 47 comprising an intermediate layer 3 and inner layer 36. An structuring layer 41 disposed intermediate the exterior layer 47 and interior layer 14 intermediate layers 3, 5. Specifically, the cutouts are formed on the exterior layer 47, intermediate layer 3 and inner layer 36 where each cutout location formed on each layer corresponds with the opposing layer cutout location. For instance, the cutouts (CO) and incision 32 on the wrist sleeve portion 9 may be formed before coupling the respective layer together by an rotary tool, laser or any suitable tool or machine. This way the cutouts and slits are formed on the exterior layer 47, intermediate layer 3 and inner layer 36, therefore when the flexible keymat 22 is coupled to the inner layer 36 top surface each key location may arrange within the one or more cutout (CO) openings and the one or more key tops 19 may be coupled to the flexible keymat 22. Alternatively, other suitable cutting methods may also be used to form the cutouts (CO), incisions 32 and openings 51 on the wrist sleeve portion 9.

Moreover, the wrist sleeve potion 9 comprises an plurality of cutouts (CO) formed at predetermine regions of its surface. Additionally, the wrist sleeve potion 9 comprises one or more incisions 32 and openings 51 formed at the display region (DR), which may allocate the display 6 ribbon access to couple to the first flexible printed circuit 34 and the one or more sensors lens to arrange within the one or more openings 51. The display region (DR) signifies an region on the exterior layer 47 where the display assembly 13 is respectively coupled to the wrist sleeve portion 9.

Specifically, the exterior layer 47, intermediate layer 3 and inner layer 36 comprises four quarter-pie shaped cutouts (CO1), (CO2), (CO4) and (CO5) spaced respectively from one another at predetermine regions, an oval-shape cutout 3 (CO3) centering the four quarter-pie shape cutouts (CO1, CO2, CO4, CO5) and an respective spherical-shape cutout (CO6) arranged above the quarter-pie shape cutout (CO2). According to cutouts (CO1 and CO2) the curved region faces outward while the opposing pointed region faces inward. More of, spherical-shape cutout 6 (CO6) is smaller than oval shape cutout 3 (CO3). Further, the spherical-shape cutout 6 (CO6) may be formed to house an power button or power status indicator such as an light emitting dioxide (LED).

Specifically, cutout (CO1) 1 arranges at an far left-side, cutout (CO2) 2 arranges at an opposing far right-side of the wrist sleeve portion 9 slightly below the display region (DR), while cutout (CO3) 3 arranges slightly below the display region (DR) intermediate cutout 4 (CO4) and cutout 5 (CO5) while cutout 6 (CO6) arranges above cutout (CO2) 2. The cutouts formed on the wrist sleeve portion 9 allocates the one or more key tops 19 (e.g., physical input buttons) to communicable couple to one or more electrical components of the printed—circuit, and to allocate one or more components to protrude to the top side of the wrist sleeve portion 9.

Additionally, the wrist sleeve portion 9 further comprises one or more means of securing the wrist sleeve portion 9 to the user wrist or forearm such as an hook and loop-type fastener such as Velcro® or other connecting means such as a buckle or snaps. In the preferred embodiment the front region of the wrist sleeve portion 9 comprises three respective attachment strips 46 positioned at the front lower region vertically overhanging the wrist sleeve portion 9. Specifically, the attachment strips 46 is disposed at an front lower side of the wrist sleeve portion 9 below the four quarter-pie shaped keytops 19 and spherical-shape keytop 19.

Each attachment strip 46 comprises an respective quadrilateral-shaped velcro strip 133 on its inner surface disposed at the region where the attachment strip 46 overhangs away from the wrist sleeve portion 9. Further, the attachment strips 46 may be coupled to the wrist sleeve portion 9 by one or more stitching processes. The attachment strips 46 may be made of the microfiber material or another material such as an leather or flexible plastic. The velcro strips 133 may be coupled to the attachment strip 46 by one or more adhesive processes or stitching processes.

Also in the preferred embodiment, the rear region of the wrist sleeve portion 9 comprises three respective quadrilateral-shape velcro pads 27 slightly adjacent one another laterally, arranged at an lower region of the wrist sleeve portion 9 rear surface. Each velcro pad 27 arranges vertically on the wrist sleeve portion 9 rear outer surface, corresponding with the attachment strip 46 velcro strip 133 when the front region is pulled towards the rear region. Further, the attachment strips 46 may be coupled to the wrist sleeve portion 9 by one or more adhesive or stitching processes.

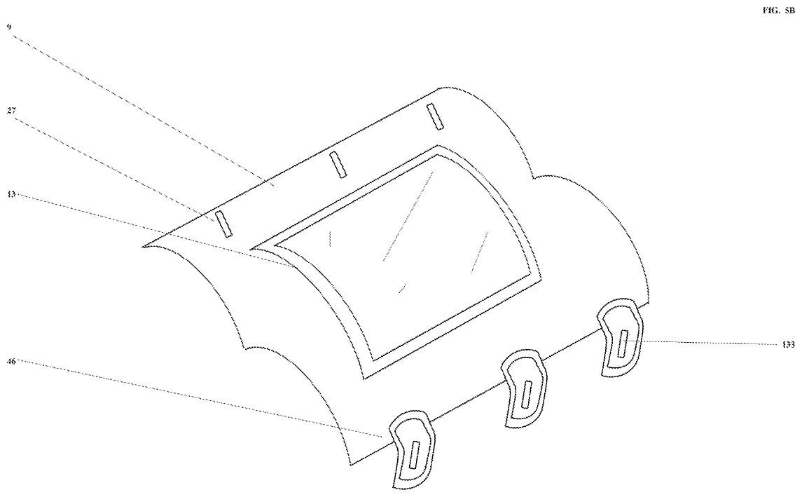

FIG. 6 illustrates the wrist sleeve portion 9 in conjunction with one or more electrical components integrated within the wrist sleeve portion 9. As mentioned above in FIG. 3 the wrist sleeve portion 9 comprises an exterior layer 47, intermediate layer 3, inner layer 36 and structuring layer 41. In the embodiment, the wrist sleeve portion 9 comprises an first flexible printed circuit 34 and second flexible printed circuit 72 comprising one or more micro electrical components populated onto its outer surface disposed onto the structuring layer 41 top surface.

More of, the structuring layer 41 comprises an first flexible printed circuit (FPC) 34 forming an T-shape disposed on the its top surface. Further, the first flexible printed circuit 34 comprises an perpendicular region and lateral region, wherein the lateral region is lengthier than the perpendicular region and wherein the lateral region is disposed beneath the display region (DR).

For instance, the first flexible printed circuit 34 may be coupled to the structuring layer 41 top surface via applying and adhesive to its bottom surface directly coupling the first flexible printed circuit 34 to the structuring layer 41 without the intervene of other suitable structures. To do this the top surface of the structuring layer 3 may comprise an thin adhesive layer made of an thermoplastic material having an low melting point disposed on its top surface. Upon coupling the first flexible printed circuit (FPC) 34 to the adhesive layer of the structuring layer 3 the one or more electrical components may be populated onto the flexible printed circuit 34 via an adhesive or soldering bond without degrading the prior layers.

In addition the structuring layer 41 comprises an second flexible printed circuit (FPC) 72 forming an quadrilateral-shape disposed on the its top surface. Specifically, the second flexible printed circuit 72 is disposed at laterally at an lower region of the structuring layer 41, beneath CO1, CO2, CO3, CO4 and CO5. In addition, the second flexible printed circuit 72 may comprise an dome sheet comprising one or more contact pads for obtaining contact from the one or more keydome switches 28.

Further, the micro-electrical components populated onto the first and second flexible printed circuit 34, 72 is one or more processors, light emitting diodes (LEDs), an input module, wireless communication module, one or more memory(s), power management module, audio modules, camera modules and a sensing module.

The first and second flexible printed circuit 34, 72 may comprise one or more thin coatings or layers of an transparent conductive overcoat (TCO) or indium tin oxide (ITO) or the like) disposed on its top surface thereof, and with a metallic layer or coating (such as an opaque or partially opaque or partially transparent metallic layer or coating, such as, for example, a copper layer or coating, a chromium layer or coating, a niobium layer or coating, a neodymium layer or coating, a silver layer or coating, a molybdenum layer or coating, and/or a layer or coating of alloys of the mentioned metals).

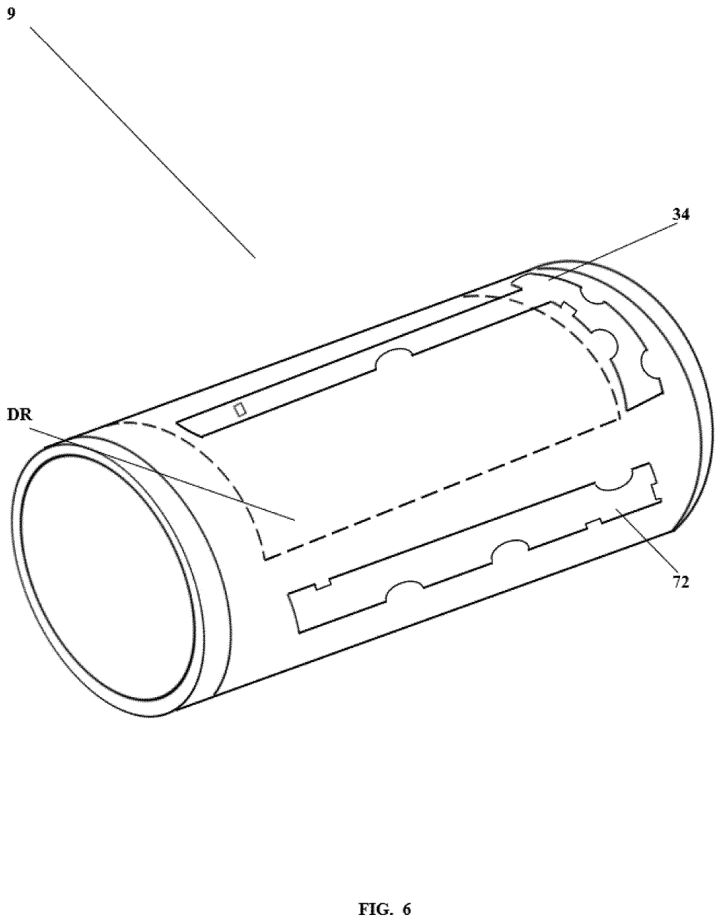

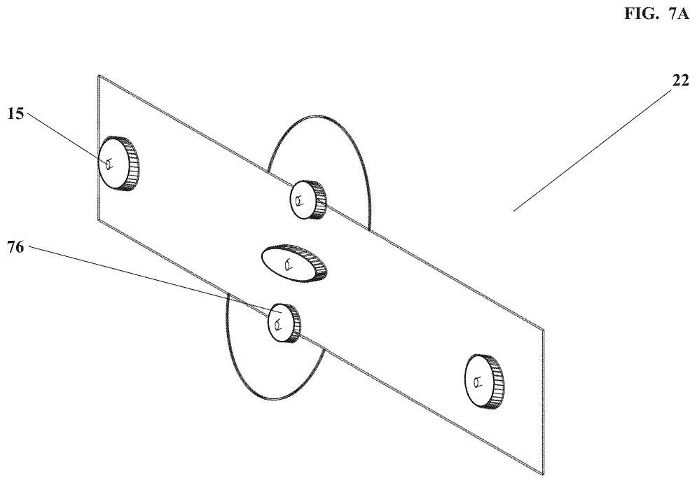

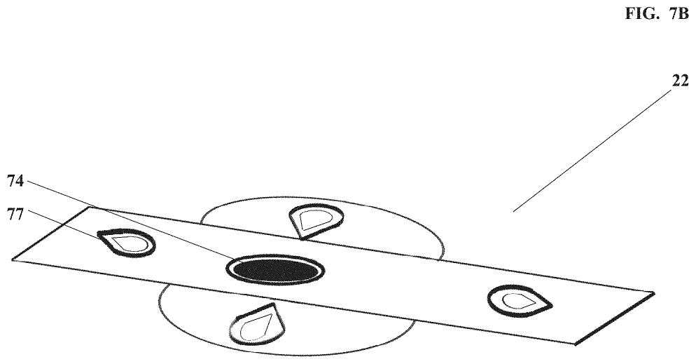

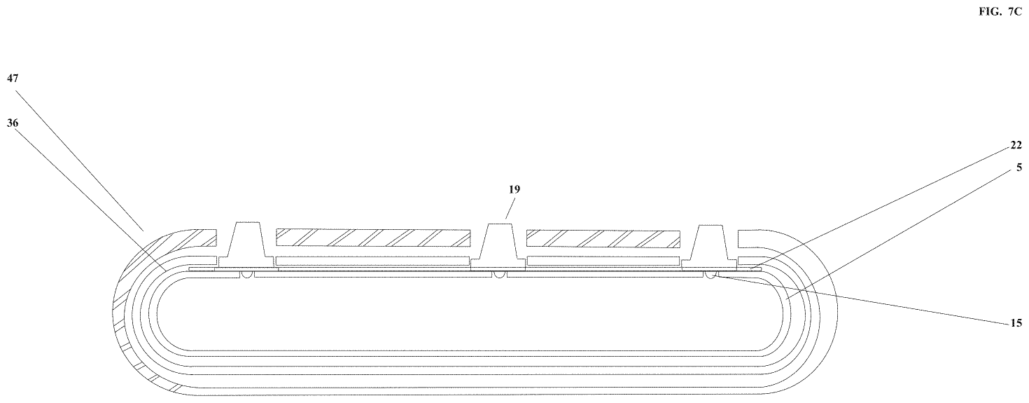

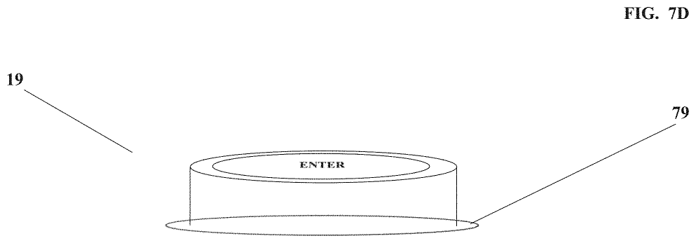

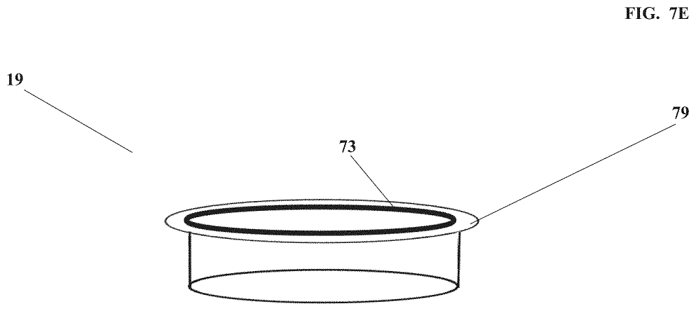

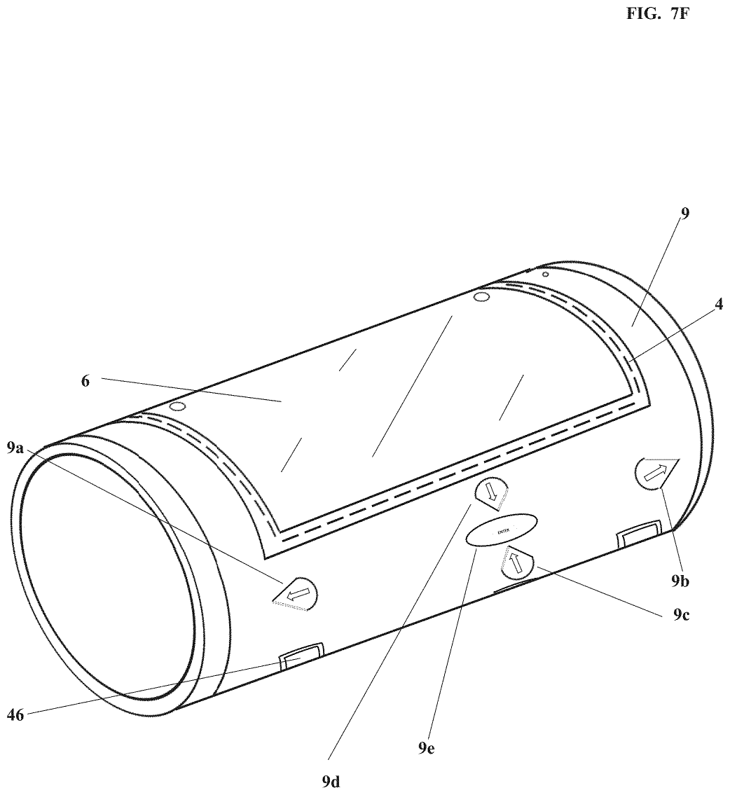

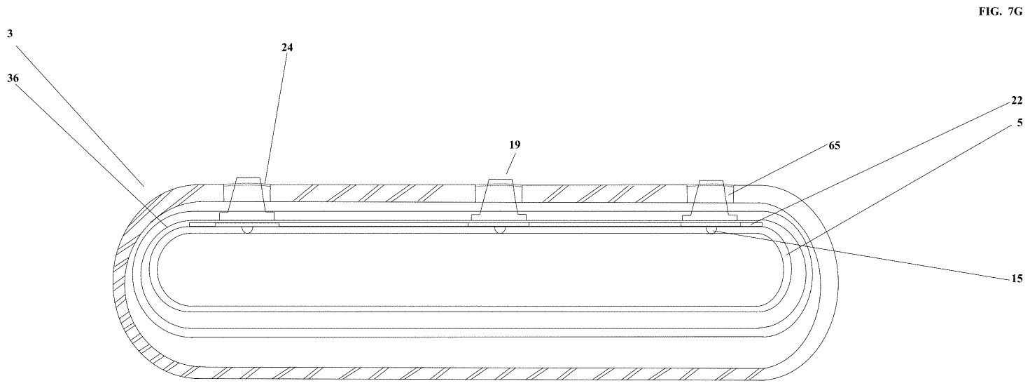

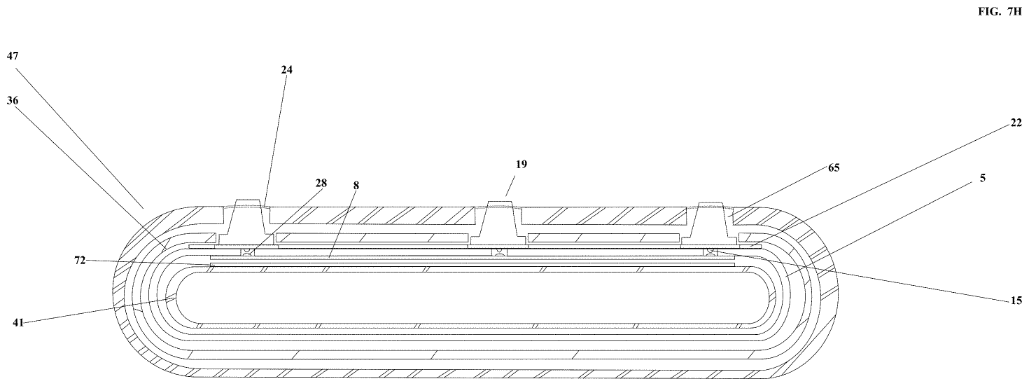

Further FIG. 7A is an rear view of the flexible keymat 22. FIG. 7B is an front view of the flexible keymat 22. FIG. 7C is an cross-view of the flexible keymat 22 disposed on the one or more layers of the wrist sleeve portion 9. FIG. 7D is an top view of the key top 19. FIG. 7E is an bottom view of the key top 19. FIG. 7F is an illustration of the one or more key tops 19 disposed on the wrist sleeve portion 9. FIG. 7G is an cross-sectional view of one or more additional components disposed on the exterior layer 47 of the wrist sleeve portion 9. FIG. 7G is an cross-sectional view of one or more additional components integrated within the wrist sleeve portion 9.

As mentioned above the wrist sleeve portion 9 structuring layer 41 top surface comprises an second flexible printed circuit 72 disposed at it top surface comprising an plurality of contact pads for obtaining contact from the keydome switches 28, in response to an user depressing the one or more key tops 19 on the flexible keymat 22.

The keyboard assembly comprises an flexible keymat 22 forming an quadrilateral-shape segment having an circular region at an mid region of it body. The flexible keymat 22 is further made or an light-transmitting silicon rubber, or an thermoplastic elastomer, i.e., a light-transmitting, flexible rubber material. Further, the flexible keymat 22 forms an thin structure layer having an partial recessed region 74 at the front side of each key location, whereas the partial recessed region 74 constitutes an slight bulge 76 at the rear side of each key location, and further comprising an upward projecting lip 77 at the front side of each key location rim FIGS. 7A & 7B. For example, the key dome keymat actuator 15 disposed at each key location bulge 76 may allocates interaction with an respective key dome switch 28, in response to an user depressing an respective key top 19.

More of, the flexible keymat 22 comprises six respective key locations formed on its top surface, and arranging within the wrist sleeve portion 9 cutouts when assemble to the inner layer 5 top surface. Specifically, the flexible keymat 22 comprises an quarter-pie shape key location to the far right and far left side of its top surface, an respective spherical-shape key location in the center of the flexible keymat 22 circular region, an quarter-pie shape key location above and below the spherical-shape key location at the flexible keymat 22 circular region. Further, one or more grooves may be located between the rows of key dome keymat actuators 15 at the region of the flexible keymat 22 where the circular region is formed due to more than one key locations arranging near each other. The grooves may be configured to allocate a user to selectively engage with an respective key dome switch 28 without interfering with an nearby opposing key dome switch 28.

Further, the flexible keymat 22 rear surface is disposed at the top surface of the a intermediate layer 5 by any suitable adhesive.

For instance, beads of adhesive may be applied to predetermine regions of the intermediate layer 5 top surface where the flexible keymat 22 may be disposed, further the flexible keymat 22 key locations may be aligned with the cutouts (COs) formed on the inner layer 36 and exterior layer 47 from an lateral perspective FIG. 7C.

Furthermore, an respective key top 19 for each key location is disposed at the top surface of the flexible keymat 22. The key tops 19 forms an hollow structure having an circling recessed region 73 slightly adjacent the flanged edges 79 at its inner base surface. Each respective key top 19 circling recessed region 73 allocates the recessed region 73 to assemble on top of the keymat 22 projecting lip 77 at each key location. The key tops 19 body lower region comprises an slight flanged edge 79 prolonging outwardly. The key tops 19 may be further defined as plunger style key tops 19 FIGS. 7D & 7E. Further, the key tops 19, is preferably made of flexible or semi-flexible materials such as plastic, thermoplastic, ethylene vinyl acetate (EVA), Kraton styrene polymer material, PVC, ENGAGE, polyethylene polymer, an light-transmitting silicon rubber, an thermoplastic elastomer or an (e.g., a light-transmitting, flexible rubber material. Alternatively, the keytops 19 may comprise an color other than an transparent clear such as black, red, blue, green, gray and yellow. Specifically, the key tops 51 are formed from an material having an heavier density than the flexible keymat 22. The key tops 19 is adhered on top of the flexible keymat 22 with elastic glue or other suitable adhesives between the key top 19 and flexible keymat 22.

The flexible keymat 22 comprises five respective key tops 9a-9e that corresponds with the wrist sleeve portion 9 quarter-pie shaped cutouts (CO), spherical-shape cutout (SCO) and flexible keymat 22 key locations.

Specifically, the flexible keymat 22 comprises an quarter-pie shape key top 9a at an far left region disposed at cutout 1 (CO1), an quarter-pie shape key top 9b at an far right region disposed at cutout 2 (CO2), an oval-shape key top 9e disposed at cutout 3 (CO3), an respective quarter-pie shape key top 9c disposed at cutout 5 (CO5) below the oval-shape key top 9e and an respective quarter-pie shape key top 9d disposed at cutout 4 (CO4) above the oval-shape key top 9e FIG. 7F.

Moreover, each respective quarter-pie key top (9a-9d) comprises an arrow symbol formed on its top surface that points at the direction corresponding to the pointed tip of each respective key top 19. For instance, the direction of the arrow symbol pointed end may correspond with the direction of the key top 19 pointed end. Further, key top 9e comprises the word ENTER formed in its top surface. For instance, each respective key top 19 may be black or an non-transparent color but the arrow symbol and word ENTER disposed on the key tops 19 may be transparent allocating light to pass through.

Specifically, when key top 9a is depressed this input refers to toggling an curser to the right. When key top 9b is depressed this input refers to toggling an curser to the left. Further, when key top 9c is depressed this input refers to toggling an curser to the downward. However, when key top 9d is depressed this input refers to toggling an curser to the upward. Further, when key top 9e is depressed this input refers to an input command for selecting an item. For instance, each respective key top 19 may be black or an non-transparent color but the arrow symbol and word ENTER disposed on the key tops 19 may be transparent allocating light to pass through.

Though when the key tops 19 are disposed on the flexible keymat 22 the exterior layer 47 and inner layer 36 may overlap the key top 19 flange edges 79 leaving an partial spacing 65 intermediate the an lower region of the key tops 19 and exterior layer 47 from an lateral perspective. Therefor, an trim member 24 is disposed around each respective key top 9a-9e at the top surface of the exterior layer 47 that covers the partial spacing 65.

Specifically, the exterior layer 47 comprises four respective trim members 24 forming an quarter-pie shape corresponding with key tops 9a-9e and two trim member 24 forming an oval-shape corresponding with key top 9e and cutout 6 (CO6).

Specifically, the top surface of the exterior layer 47 comprises an respective quarter-pie shape trim member 24 disposed at key top 9a, an quarter-pie shape trim member 24 disposed at key top 9b, an oval-shape trim member 24 disposed at key top 9e, an respective quarter-pie shape trim member 24 disposed at key top 9c, an respective quarter-pie shape trim member 24 disposed at key top 9d and an respective oval-shape trim member 24 disposed at cutout 6 (CO6) FIG. 7G.

The trim members 24 are approximately 1.5 mm to 3 mm according to thickness. The trim members 24 may be made of an flexible or non-flexible plastic, metal, aluminum, an light-transmitting silicon rubber, or an thermoplastic elastomer, (e.g., a light-transmitting, flexible rubber material), or other suitable materials may be used. For instance, the trim member 24 may be coated with one or more colors or chrome or gold plated. The trim members 24 is disposed on the exterior layer 47 top surface by any suitable adhesive, where adhesive is applied to its bottom surface of the trim member 24 and the trim member 24 is disposed onto the exterior layer 47 top surface within the partial spacing region.

Moreover, the keyboard assembly comprises an respective keydome layer 8 disposed intermediate the flexible keymat 22 and second flexible printed circuit 72 forming an thin flexible sheet-like structure. The keydome layer 8 may be made of an flexible foil, plastic conductive material other suitable flexible conductive materials may also be used. The keydome layer 8 comprises an plurality of keydome switches 28 disposed on its top surface that comes in contact with the one or more contact pad disposed on the second flexible printed circuit 72 generating one or more electrical signals to the second flexible printed circuit 72, in response to an user depressing an respective key top 19 and the key dome keymat actuators 15 coming in contact with an respective keydome switch 28 (e.g., depressing the keydome switch 28) formed on the keydome layer 4.

The keydome layer 8 constitute an insulating foil, preferably plastic foil, where one or more metallic keydome switches 28 are disposed at each key location so that the metal dome may be attached to the insulating foil facing to the second flexible printed circuit 72 but not contacting the contact pads on the second flexible printed circuit 72 if an respective key top 19 is not depressed. Further, the keyboard assembly keydome layer 8 is disposed between the flexible keymat 22 and second flexible printed circuit 72 at the rear surface of the intermediate layer 5 where each keydome switch 28 is located in the openings of the intermediate layer 5 FIG. 7H.

Further, the keydome layer 8 is disposed onto the rear surface of the intermediate layer 5. The keydome layer 8 is coupled to the intermediate layer 5 by any suitable adhesive.

The second flexible printed circuit 72 may also comprise one or more light emitting diodes (LEDs) or other light sources disposed on its top surface configured to illuminate the transparent or translucent flexible keymat 22, key tops 19 and trim members 24. For instance, the intermediate layer 5, inner layer 36, and keydome layer 8 may comprises one or more openings corresponding with each other that may allocate light emitted from the one or more LEDs to illuminate the one or more keytops 19, flexible keymat 22 and trim members 24.

The keymat 22 keytops 19 and keydome switch actuators 15 are positioned according to the location of the keydome switches 28 arranged on the bottom surface of the inner layer 3.

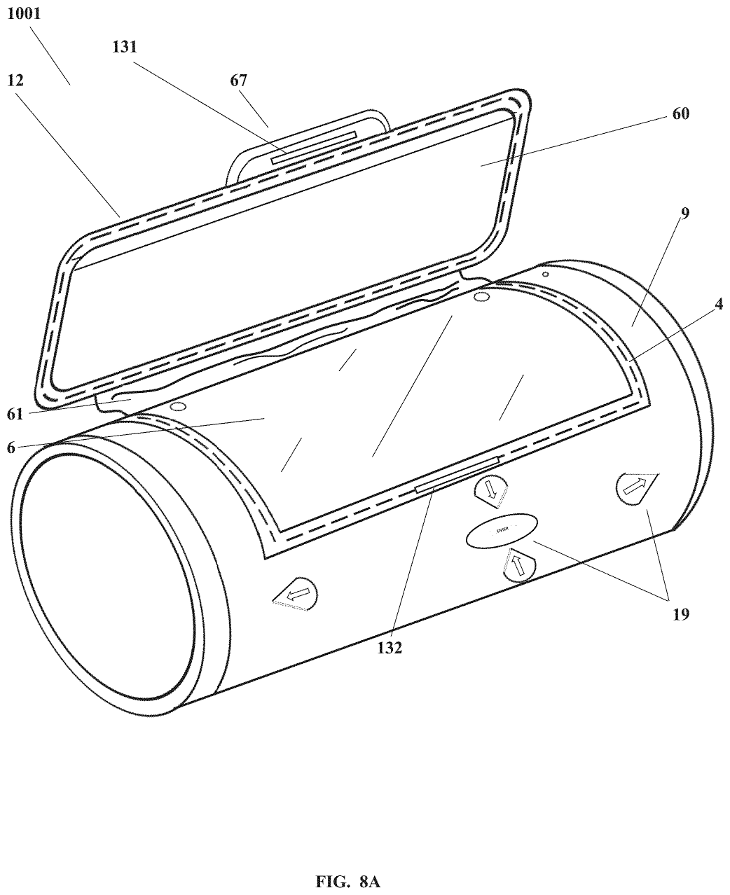

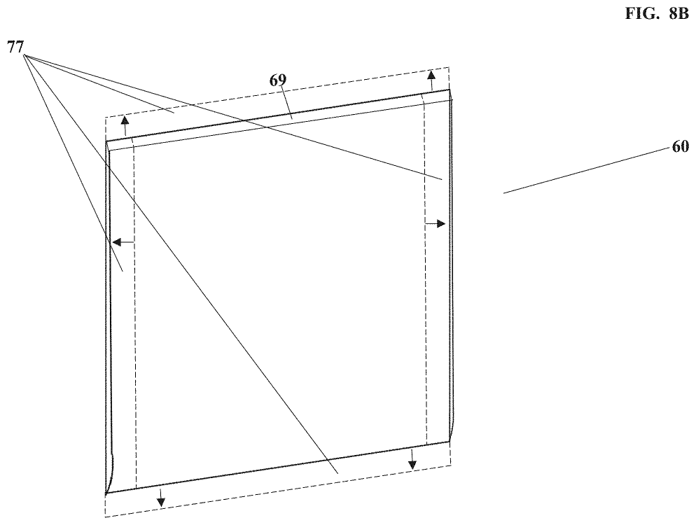

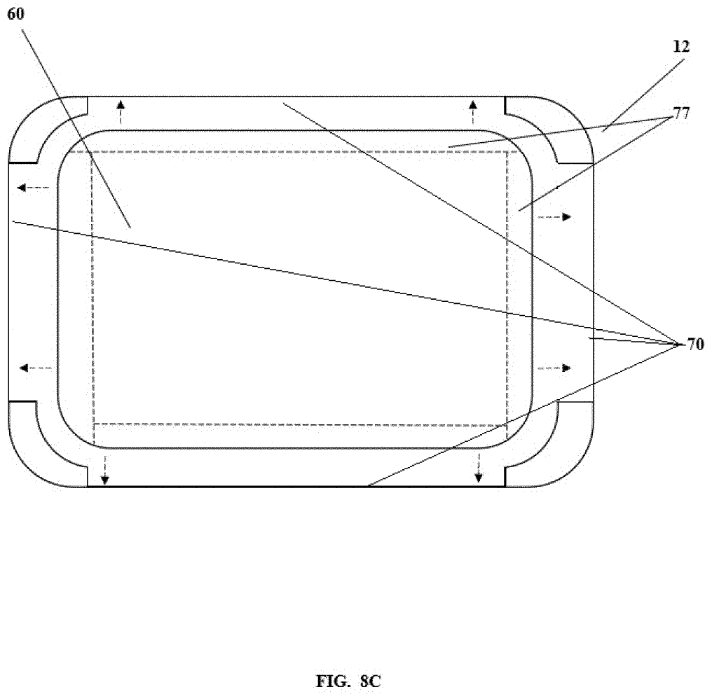

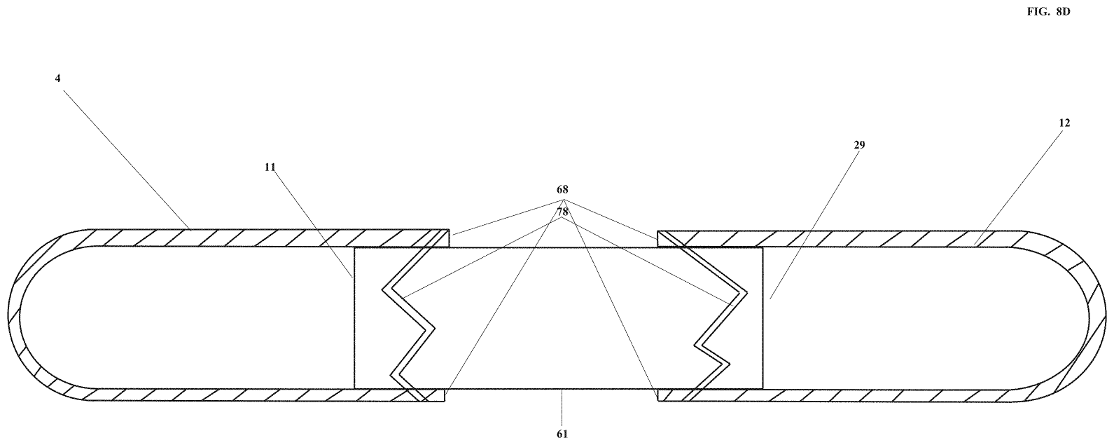

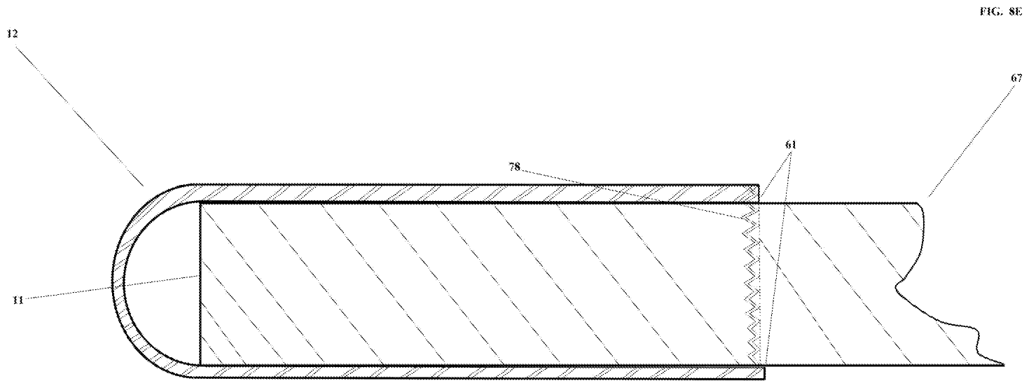

Referring to FIG. 8A, shows the terminal 1001 having an flexible display assembly 13 and an respective flap assembly 12 that may be referred to as an folding type terminal. Further, when the terminal 1001 comprises an flap assembly 12 the terminal is capable of being open and close via an intermediate segment 11.

Further, the flap assembly 12 comprises an respective flexible plastic sack 60 comprising an inserting region 69 and an respective pull-tab 67 which allocates the flap assembly 12 to be separated from the display assembly 13 via an user pulling the pull-tab 67 at a direction away from the display assembly 13.

FIG. 8B is an illustration of the flexible plastic sack 60. FIG. 8C is an illustration of the flexible plastic sack 60 disposed within the flap assembly 12. According to the preferred embodiment, the flexible display assembly 13 may comprise the same components and structuring as the flexible display assembly 13 disclosed previously above. FIG. 8D is an cross-sectional view illustrating how the flexible display assembly 13 is coupled to the flap assembly 12. FIG. 8E is an cross-sectional view illustrating how the pull-tab 67 is coupled to the flap assembly 12.

In the preferred embodiment, the flexible flap assembly 12 forms an reedy quadrilateral-shape with outer edges that partially curve. The flap assembly 12 forming an quadrilateral-shape comprising an center opening 10 that prolongs outwardly leaving in the range of 11.43 mm and up of the flap assembly 12 constituting an window (e.g., center opening). The flap assembly 12 may be made of an silicone rubber, leather or flexible plastic material. The flap assembly 12 comprises an thickness of approximately 1.27 mm and up, corresponding with the dimensions of the flexible display assembly 13. For instance, to form the flap assembly 12 one or more layers of rubber, leather or plastic materials may be laminated together, 3D-printed or any other methods known to one skilled in the art(s) to form the flap assembly 12.

In addition, the flap assembly 12 comprises an flexible plastic sack 60 disposed within its center opening 10 (e.g., window) comprising an inserting region 69 configured to house an play-card or the likes. The flexible plastic sack 60 may be made of materials such as an transparent plastic. However, upon coupling the flexible plastic sack 60 to the flap layer 12, the flexible plastic sack 60 comprises in the range of 3 mm and up of excess film 77 at its top, bottom and side region this allocate the flexible plastic sack 60 to be disposed within the flap assembly 12 inner lips 70 FIG. 8B.

In order to couple the flexible plastic sack 60 to the flap assembly 12 the flap assembly 12 inner lips 70 is partially bifurcated to allocate the flexible plastic sack 60 excess film 77 (begins at dashed lines) to be inserted within the inner lips 70, an small amount of adhesive may be applied to the inner surface of the inner lips 70, the flexible plastic sack 60 excess film 77 is then disposed within the inner lips 70 and flap assembly 12 is stitched 78 at one or more regions near its boarding (e.g., outer edges and an opposing predetermine region) coupling the flexible plastic sack 60 within the flap assembly 12. The flexible plastic sack 60 is coupled to the flap assembly 12 via an stitching and adhesive process FIG. 8C.

However, the present embodiment, shows the flexible display assembly 13 and flap assembly 12 in relations to one another via an intermediate segment 61 disposed intermediate the flexible display assembly 13 and flap assembly 12. Further, the intermediate segment 61 forms an quadrilateral-shape thin strip form preferably from an flexible material. The intermediate segment 61 can be made of an thin flexible material such as silicone rubber, leather, plastic, an fabric or other suitable materials may be used. The intermediate segment 61 comprises an thickness of in the range of 1.27 mm and up.

To couple the intermediate segment 61 to the flexible display assembly 13 and flap assembly 12 the flexible window layer 4 top outer lips 68 and flap assembly 12 bottom outer lips 68 are partially bifurcated to allocate the intermediate segment 61 distal edges 11, 29 to be inserted within the outer lips 68, an small amount of adhesive is applied to the inner surface of the outer lips 68, the intermediate segment 61 distal edges 11, 29 is then disposed within the outer lips 68 and the display assembly and flap assembly is stitched 78 at one or more regions near its boarding (e.g., outer edges and an opposing predetermine region) coupling the intermediate segment 61 to the flexible window layer 4 and flap assembly 12 FIG. 8D.

Furthermore, the flap assembly 12 comprises an pull-tab 67 disposed laterally at an central top region of the flap assembly 12. Specifically, the pull-tab 67 body forms an quadrilateral-shape thin strip. The pull-tab 67 can be made of an thin material such as silicone rubber, leather, plastic, an fabric other suitable materials may be used. The pull-tab 67 comprises an thickness in the range of 3.21 mm and up.

Moreover, in order to couple the pull-tab 67 to the flap assembly 12 the top region of the flap assembly 12 lips 61 are partially bifurcated to allocate the pull-tab 67 distal edges 11 to be inserted within the lips 61, an small amount of adhesive is applied to the inner surface of the lips 61, the pull-tab 67 distal edges 11 is then disposed within the lips 61 and the lips 61 are stitched 78 closed at one or more regions (e.g., outer edges and an opposing predetermine region) coupling the pull-tab 67 to the flap assembly 12 FIG. 8E.

Further, the pull-tab 67 comprises an respective attaching mechanism 131 disposed laterally at an midway region of its interior surface. The attaching mechanism 131 may allocate the flap assembly 12 and flexible widow housing 4 to respectively attach to one another at an locking fashion. The attaching mechanism 131 may be an velco strip or magnet and may be coupled to the pull-tab 67 by any suitable adhesives. More of, the flexible window housing 4 comprises an respective attaching mate/pad 132 disposed laterally at an lower midway region of its exterior surface. The attaching mate/pad 132 may be an velco pad or magnet and may be coupled to the flexible window housing 4 by any suitable adhesives.

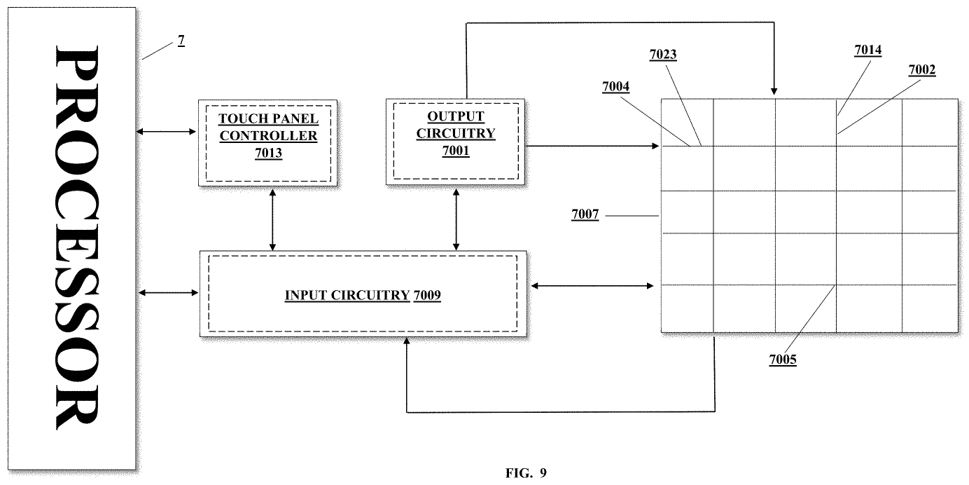

FIGS. 9 & 10 are illustrations showing embodiments of the an touch panel sensor system 7000 of a terminal 1001 display for determining an location of an object and executing at least one function of the object based upon an user interaction with the object according to the present invention. Touch panel sensor system 7000 includes an touch panel sensor 7007 for sensing an user interaction (e.g., pressing and/or swipe gesture touch even) over an predetermine area of the touch panel, one or more output circuitry 7001, one or more input circuitry 7009, and a touch panel controller 7013 communicable coupled to the touch panel sensor 7007.

In most instances, the touch panel sensor 7007 can consist of one or more capacitive sensing mediums having one or more row traces (e.g., electrodes), or driving lines 7004, and one or more column traces (e.g., electrodes), or one or more sensing lines 7014, to detect at least a change in capacitance in response to an user interaction (e.g., pressing and/or swipe gesture of the touch panel) performed over a surface of the touch panel of the display 6. And henceforth, the touch panel sensor 7007 can be configured to recognize the user interaction, relative position and the magnitude of the user interactions performed over the surface of the display 6.

In other instances, the row and column traces can be perpendicular to each other in a way such that the row and column traces can define a coordinate system and each coordinate location comprises a capacitor formed at an intersection 7005 of the row and column traces. Further, the touch panel controller 7013 can be configured to interface with the touch panel sensor 7007 to energize the touch panel sensor 7007 (e.g., stimulate the driving lines) and to detect (e.g., read) the change in capacitance from the sensing lines. For instance, the touch panel controller 7013 can comprises firmware and/or application specific integrated circuitry (ASIC) configured to drive the one or more driving lines 7004 (e.g., drive channels). The controller 7013 may comprise firmware and/or ASIC that provides processing functionality to the touch panel sensor system 7000.

Furthermore, in other instances, one or more processor(s) 7 may be communicable coupled to the touch panel controller 7013 in order to provide processing functionality to the touch panel sensor system 7000. In most cases, the one or more processor(s) 7 can be configured to provide executable instructions to the touch panel controller 7013 based upon an user interaction (e.g., pressing and/or swipe gesture touch event) of the touch panel of the display 6, and to obtain one or more signals representing capacitive values from the controller 7013 and to determine an start and end positions of an user interaction (e.g., pressing and/or swipe gesture touch event) over the touch panel sensor 7007.

Further, the touch panel controller 7013 consist of an output circuitry 7001 configured to output one or more drive signals having an characteristics of an waveform that drive the one or more driving lines 7004. The controller 7013 also comprises an sensing circuitry 7006 for measuring a change in capacitance due to a touch event performed over the touch panel controller 7013.

The sensor driver can be a digital to analog converter (DAC) 7017 electrically connected to a one or more buffer(s) 7019. The one or more buffer(s) 7019 is electrically connected to one or more respective driving line 7004.

In some instances, a subset of electrodes (e.g., rows 7023 or columns 7002) may be charged by driving corresponding electrodes with a predetermined voltage signal having a waveform corresponding to a particular frequency characteristic. In this instance, the controller 7013 is configured to sense a change in mutual-capacitance by measuring a change in mutual capacitance between a non-intersecting non-driven electrode (e.g., row 7023 or column 7002) and the driven electrode (e.g., row 7023 or column 7002) due to an user interaction (e.g., swipe gesture, pressing gesture touch event). For instance, the controller 7013 is configured to drive one or more electrodes (e.g., rows 7023 or columns 7002), and the controller 7013 is configured to measure the mutual capacitance between the driven electrode(s) and non intersecting non-driven electrode(s).

Further, the touch panel controller 7013 is configured to measure the mutual-capacitance between a driven electrode 7022 and non-intersecting non-driven electrode 7025. For instance, the one or more electrodes can be arranged in a parallel or substantial parallel configuration (e.g., electrodes that are not exactly parallel due to design considerations or fabrication processes).

Generally, the innovative concept of the invention is to measure the touch event events performed over a touch panel based upon an user interaction over the touch panel of the display 6.

During this action each respective intersection 7005 of the driving lines 7004 and the sensing lines 7014 can represent pixel 7015 that has a characteristic mutual-capacitance. For instance, an external object such as a user finger or stylus that moves towards a corresponding pixel 7015 to generate an electric field present between the corresponding row and column intersection, which causes a decrease in the mutual-capacitance at that location. During operation, each row (or column) may be sequentially charged by driving the corresponding drive line 7004 with a predetermined voltage signal having a waveform corresponding to a particular frequency characteristic. The capacitance of each intersection 7005 is measured. That is, the input circuitry 7009 is configured to measure capacitive coupling of the drive signals between the drive lines 7004 and the sensing lines 7014 in order to determine the capacitance of the user interaction (e.g., pressing and/or swipe gesture touch even) with respect to each node (e.g., an intersection 7005 pixel 7015).

Also during this operation of the concept, the controller 7013 mainly generates the drive signals necessary to measure or determine the change in capacitance within the touch panel sensor 7007. For instance, the controller 7013 is configured to cause the output circuitry 7001 to generate an output signal occurring within a predefined range of frequencies. The sensing circuitry 7006 can be configured to determine an charge transferred in a given time to detect changes in capacitance at each node. The sensing circuitry 7006 may comprise a plurality of integrator devices 7003 coupled to a corresponding sensing line 7014. Such integrator devices 7003 can comprise of one or more charge amplifier(s) 7016 having at least one capacitor (C) 7012 communicable coupled between one or more inverting terminal(s) 7010 and one or more output terminal(s) 7008 of the one or more charge amplifier(s) 7016. The one or more charge amplifier 7016 can also consist of a non-inverting terminal 7018. The one or more charge amplifier(s) 7016 can also be configured to transfer the input charge from the sensing lines 7014 to the integrating capacitor 7012 in order to generate an output voltage at the output 7021 at least approximately equal to the voltage across the capacitor 7012.

The output 7021 of the one or more charge amplifier 7016 is electrically connected to one or more demodulator device(s) 7020. The one or more demodulator device(s) 7020 comprises one or more ana log-to-digital converter (ADC).

Further, the touch panel controller 7013 can consist of an output circuitry 7001 configured to output drive signals of waveform makeup that can drive the driving lines 7004 of the touch panel sensor 7007, an digital to analog converter 7017 communicable coupled to one or more buffer(s) 7019, and the one or more buffer(s) 7019 can be communicable coupled to respective driving line(s) 7004, input circuitry 7009 configured to measure (e.g., detecting) a change in capacitance due to a user interaction (e.g., swipe gesture, pressing gesture, touch event, etc.) performed over the touch panel sensor 7007 of the display 6 and a start and end position of the user interaction (e.g., swipe gesture touch event) over the touch panel sensor 7007.

Additionally, the controller 7013 can be configured to cause the input circuitry 7009 to scan a portion or subset of rows and/or columns in parallel to determine a change in mutual-capacitance at the scanned rows or columns in an interleaved protocol to determine a change in mutual-capacitance in order to detect a user interaction (e.g., swipe or pressing gesture touch event). Input circuitry 7009 is configured to detect a change in mutual-capacitance due to an object at least partially altering the electric field. For instance, the input circuitry 7009 can be configured to detect a change in mutual-capacitance from an user interaction on the touch panel.

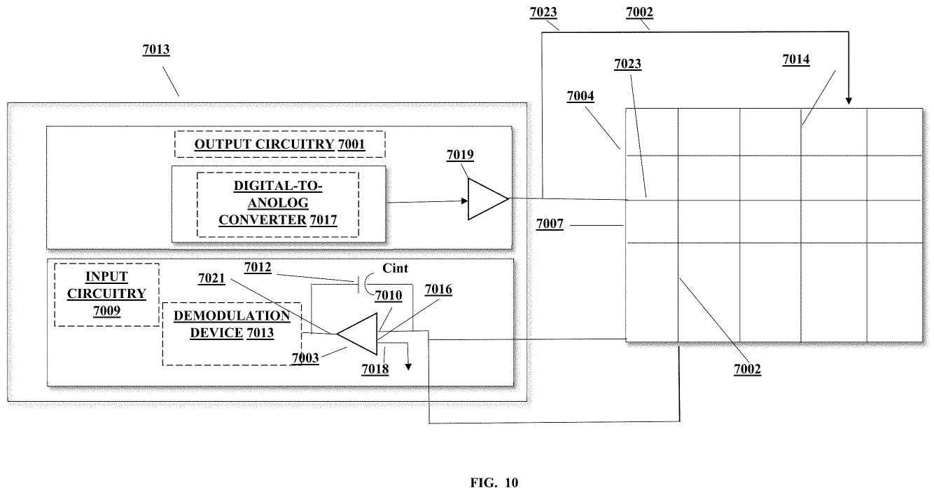

Further, the controller 7013 can be configured to drive multiple rows 7023 or columns 7002 and to sense parallel non-driven rows 7023 or columns 7002. In some instances, the output circuitry 7009 can be configured to drive multiple parallel rows 7023 or columns 7002 during a first time interval creating an electric field between the driven rows 7023 or columns 7002 and parallel non-driven rows 7023 or columns 7002. Therefore, it can be understood that multiple rows or columns can be driven while a single row or column is sensed, or two or more rows or columns may be driven while a single adjacent non-driven row or column is sensed and a single row or column may be driven while a two or more adjacent non-driven rows or columns are sensed FIG. 10.

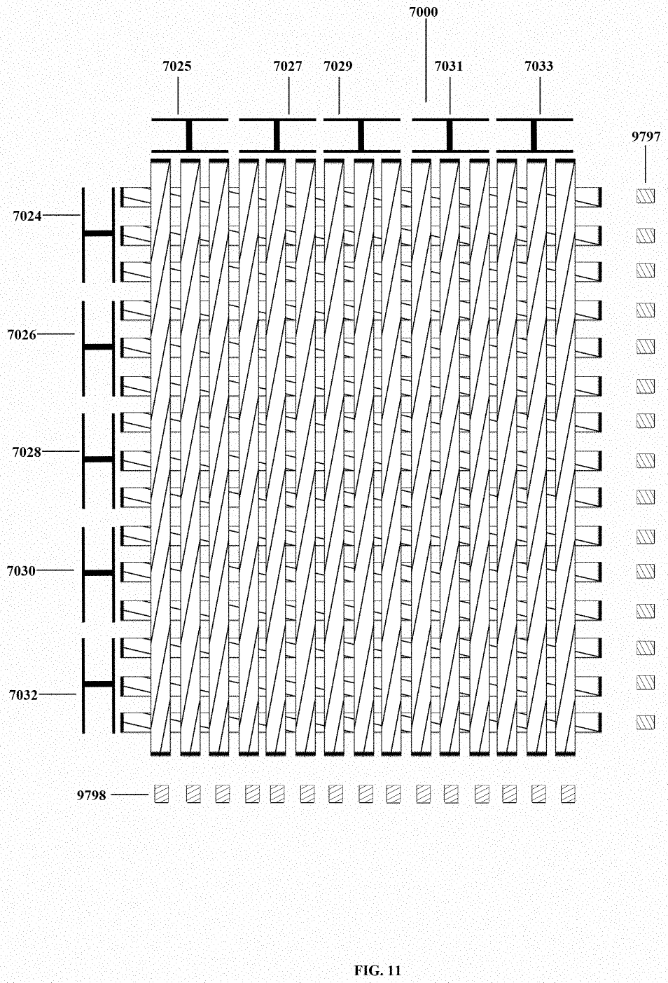

FIG. 11 is an exemplary illustration of the touch panel sensor 7000 used to of an user interaction with executing one or more functions of the object(s) 1009 on the geographical user interface 310 of the display 6. As mentioned above, in the present invention the terminal 1001 comprises of a display 6 having an touch panel sensor 7000 consisting of an plurality of rows 7023 and columns 7002 for distributing relative signal(s) strength, or relative signal magnitude measured by a input circuitry 7009 to one or more processor 7 in order to determine an predetermine precise location of an external object (e.g., user finger or stylus) used to control and/or adjust an object(s) 1009 from one area to another disposed on the geographical user interface 310 of the display 6 based upon the user interaction (e.g., pressing and/or swipe gesture touch event) with the touch panel sensor 7000 of the display 6 depicted by a graphical representation (e.g., row(s) signal 9797 and column(s) signal 9798) of an predetermine area of where the user interacts with the touch panel sensor 7000 of the display 6. Generally speaking, the row(s) 7023 and column(s) 7002 of the touch panel sensor 7000 are divided into respective subsets. Specifically, the row(s) 7023 are divided into an first row(s) geographical area 7024, second row(s) geographical area 7026, third row(s) geographical area 7028, a fourth row(s) geographical area 7030 and a fifth row(s) geographical area 7032.

The first row(s) geographical area 7024 is usually defined by the first subset of row(s) 7023 disposed at the uppermost area of the touch panel sensor 7000. The second row(s) geographical area 7026 is usually defined by the second subset of row(s) 7023 disposed below the first row(s) geographical area 7024 at an upper middle area of the touch panel sensor 7000. The third row(s) geographical area 7028 is usually defined by the third subset of row(s) 7023 disposed below the second row(s) geographical area 7026 at an lower middle area of the touch panel sensor 7000. The fourth row(s) geographical area 7030 is usually defined by the fourth subset of row(s) 7023 disposed below the third row(s) geographical area 7028 at a lower area of the touch panel sensor 7000. And the fifth row(s) geographical area 7032 is usually defined by the fourth subset of row(s) 7023 disposed below the fourth row(s) geographical area 7030 at the lowest most area of the touch panel sensor 7000.

Additionally, the column(s) 7002 are divided into a first column(s) geographical area 7025, second column(s) geographical area 7027, third column(s) geographical area 7029 and a fourth column(s) geographical area 7031 and a fifth column(s) geographical area 7033. The first column(s) geographical area 7025 is usually defined by the first subset of column(s) 7002 disposed at the far left area of the touch panel sensor 7000. The second column(s) geographical area 7027 is usually defined by the second subset of column(s) 7027 disposed at an adjacent right of the first column(s) geographical area 7025 of the touch panel sensor 7000.

The third column(s) geographical area 7029 is usually defined by the third subset of column(s) 7002 disposed at an adjacent right of the second column(s) geographical area 7027 of the touch panel sensor 7000. The fourth column(s) geographical area 7031 is usually defined by the fourth subset of column(s) 7002 disposed at the far left of the touch panel sensor 7000 adjacent the third column(s) geographical area 7029. And the fifth column(s) geographical area 7033 is usually defined by the fifth subset of column(s) 7002 disposed at the farthest left of the touch panel sensor 7000 adjacent the fourth column(s) geographical area 7031.

As previously described, the terminal 1001 consist of a display 6 having an geographical user interface for displaying one or more object(s) 1009, an input circuitry 7009 configured to measure the relative signal strength, or relative signal magnitude, for one or more row(s) 7023 and column(s) 7002 based upon the user interaction (e.g., pressing and/or swipe gesture touch event) with the touch panel sensor 7000.

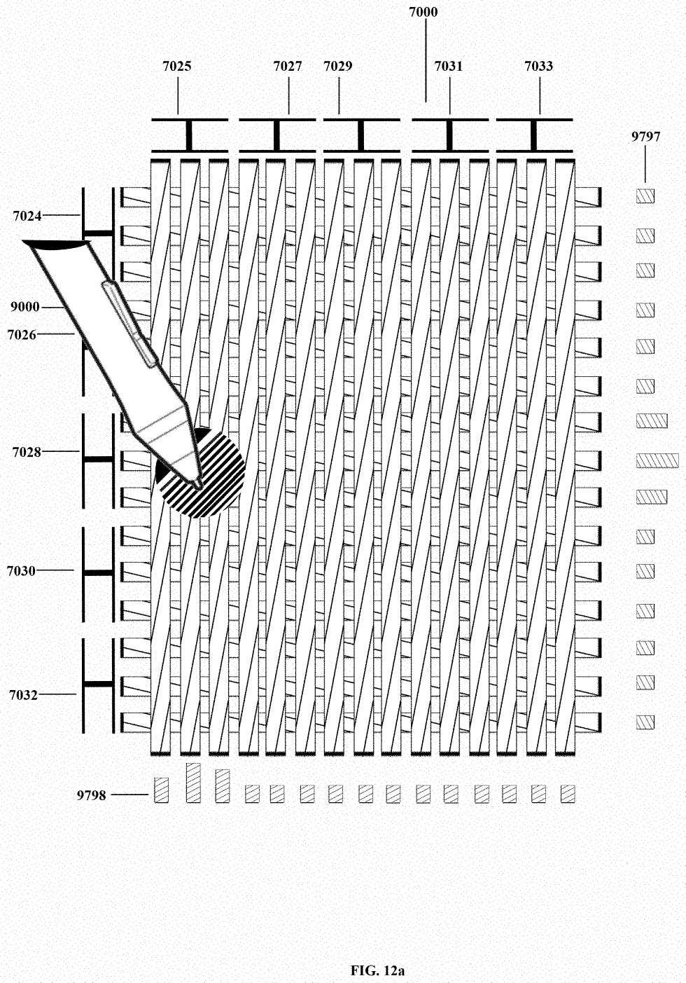

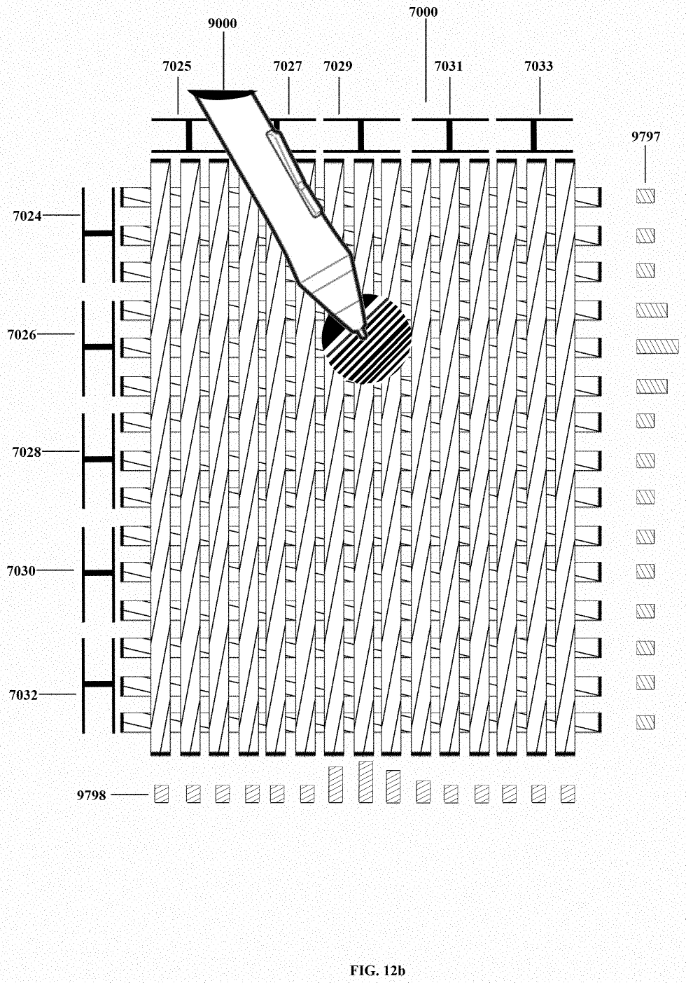

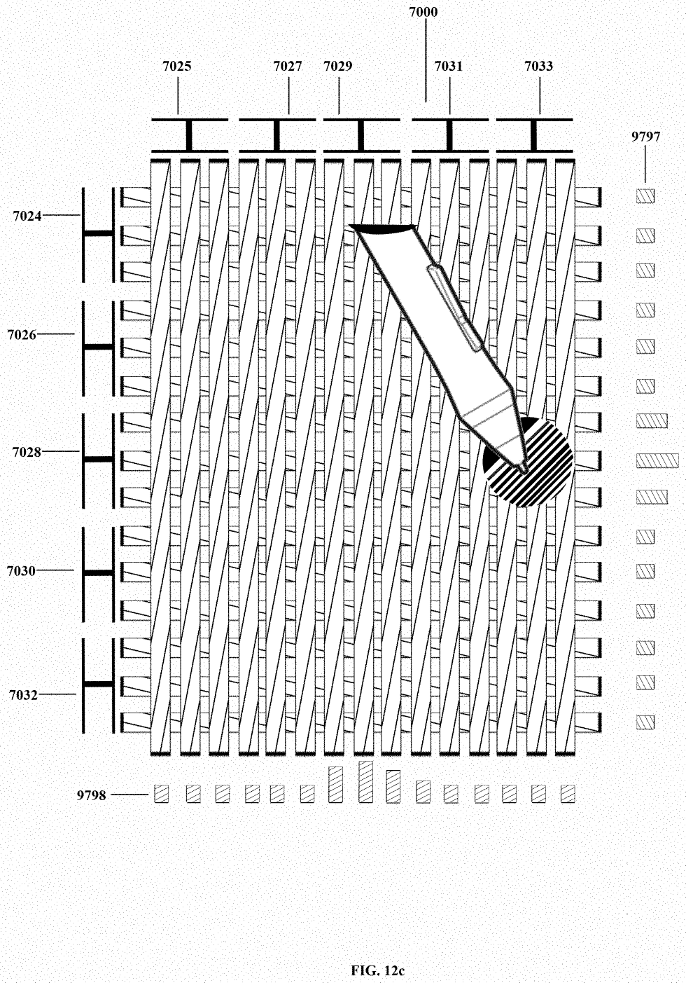

FIG. 12a-12c is illustrations showing an external object 9000 disposed over the touch panel sensor 7000 of the display 6. The external object 9000 can be any of such as an finger or stylus. As described above, the touch panel sensor 7000 is shown bifurcated into an subset(s) of row(s) 7023 and column(s) 7002 for distributing relative signal(s) strength (e.g., threshold), or relative signal magnitude measured by a input circuitry 7009 to one or more processor(s) 7 in order to determine an predetermine precise location of the external object(s) 9000 and/or object(s) 1009 to be adjusted by the external object 9000 disposed on the geographical user interface 310 of the display 6 based upon the user interaction (e.g., pressing and/or swipe gesture touch event) with the touch panel sensor 7000 of the display 6. Further, in each illustration shown is the external object 9000 positions at an respective subsets of row(s) 7023 and column(s) 7002 of the touch panel sensor 7000 of the display 6 having an respective relative signal(s) strength (e.g., threshold), or relative signal magnitude at respective areas of the graphical representation (e.g., bars) measured by the input circuitry 7009. Specifically, shown are graphical representations (e.g., bars) for each respective subset of row(s) 7023 and column(s) 7002 for determining an relative signal(s) strength (e.g., threshold) for an predetermine area at which the user interacts with the touch panel sensor 7000 of the display 6, in such instances allocating the one or more processor(s) to determine an precise location of the external object 9000 and/or object that the user of the external object 9000 is controlling (e.g., moving or adjusting). For instance, as shown in FIG. 12a is the external object 9000 placed over an area representing the subset(s) of the third row(s) geographical area 7028 and the first column(s) geographical area 7025. As shown in FIG. 12b is the external object 9000 placed over an area representing the subset(s) of the second row(s) geographical area 7026 and the third column(s) geographical area 7029. As shown in FIG. 12c is the external object 9000 placed over an area representing the subset(s) of the fourth row(s) geographical area 7028 and the fourth column(s) geographical area 7029.

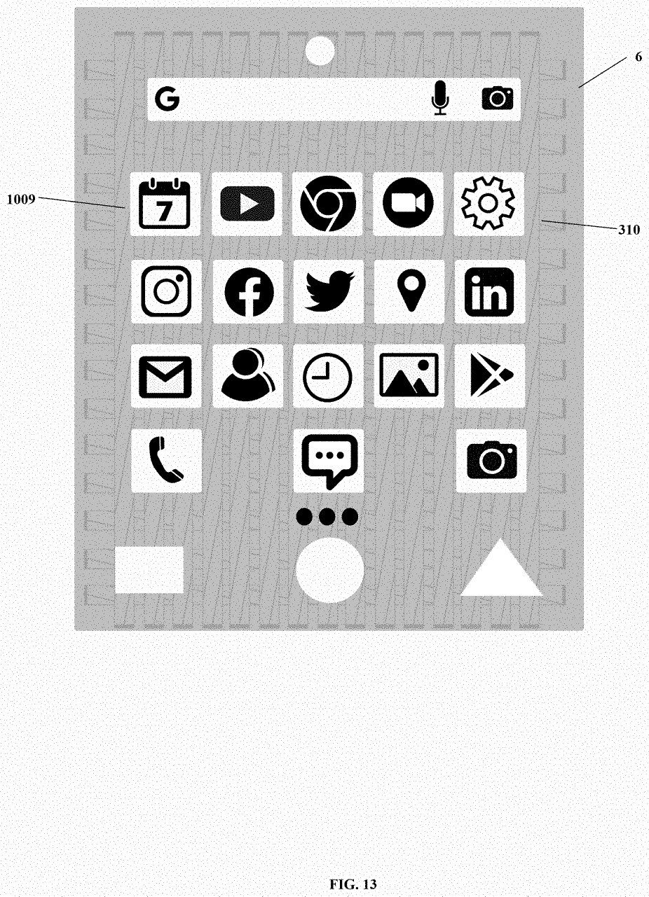

FIG. 13 is conceptual views showing an embodiment(s) of one or more object(s) 1009 disposed within an respective subset of row(s) and column(s) that an user interacts with, and that the processor(s) 7 is configured to determine an precise geographical location of on the user interface of the display 6 based upon relative signal(s) strength, or relative signal magnitude measured by a input circuitry according to an embodiment of the present invention. For instance, the one or more object(s) 1009 displayed on the display 6 may be a clickable object such as a icon, web browser, application, widget, music file (e.g., mp3 or mp4), photo, video, mobile terminal functions windows, files, alerts or other identifiable system objects. However, the user may access a web browser and cause the display 6 graphical user interface 310 to display web browser by way of a user interaction (e.g., pressing gesture touch event) with the web browser object(s) 1009 (e.g., icon), the user may place a phone call and cause the display 6 graphical user interface 310 to display phone function objects by way of a user interaction (e.g., pressing gesture touch event) with the phone function object(s) 1009 (e.g., icon), the user may access e-mail functions and cause the display 6 graphical user interface 310 to display a e-mail function object(s) 1009 (e.g., icon) by way of a user interaction (e.g., pressing gesture touch event) to the e-mail object (e.g., icon), the user may access video player functions and cause the display 6 graphical user interface 310 to display video player processing objects by way of a user interaction (e.g., pressing gesture touch event) to a video player object(s) 1009 (e.g., icon), the user may access picture/video gallery functions and cause the display 6 graphical user interface 310 to display picture/video gallery objects by way of a user interaction (e.g., pressing gesture touch event) to a picture/video gallery object(s) 1009 (e.g., icon) the user may access a mobile game/application and cause the display 6 graphical user interface 310 to display a mobile game/application function by way of a user interaction (e.g., pressing gesture touch event) to a mobile game/application object(s) 1009 (e.g., icon) and the user may access a web browser or search a particular subject, term or keyword and cause the display 6 graphical user interface 310 to display web browser or search browser by way of the user interaction (e.g., pressing gesture touch event) to a search browser object(s) 1009 (e.g., icon).

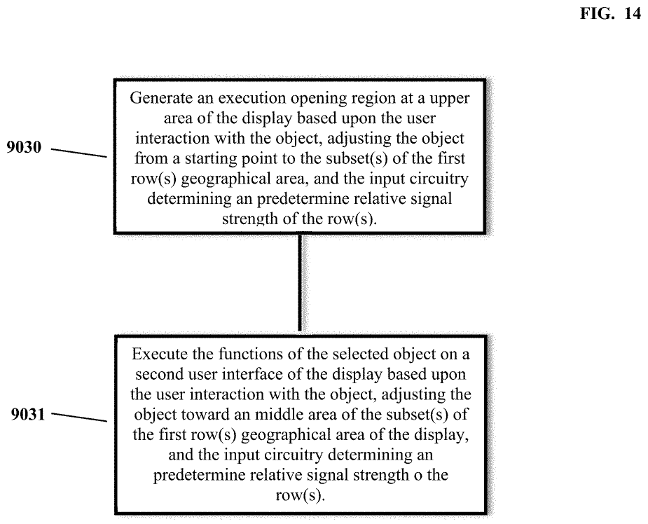

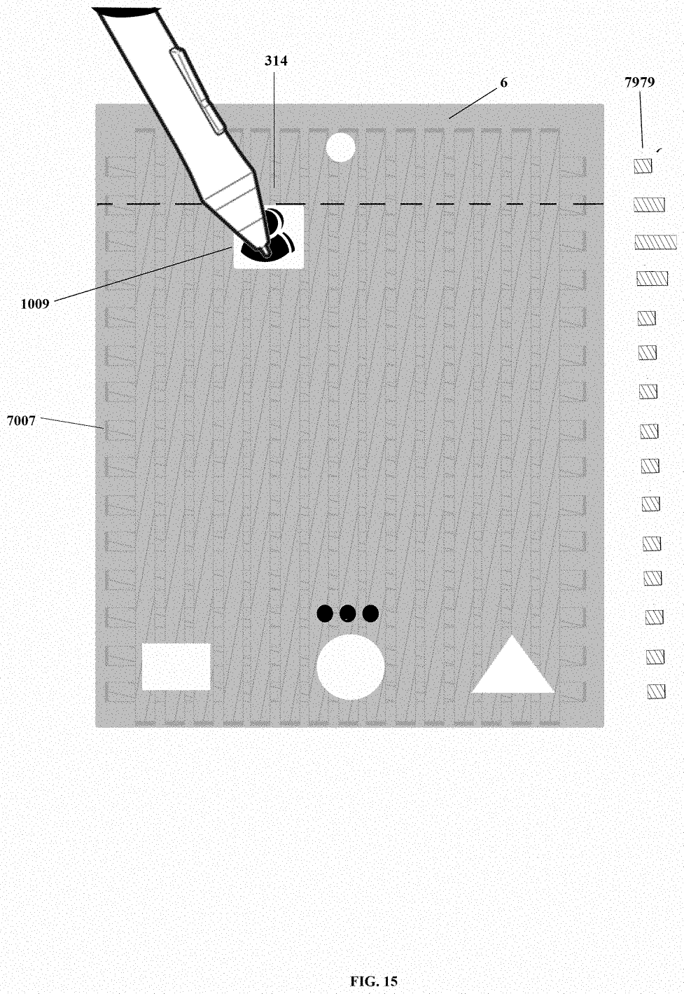

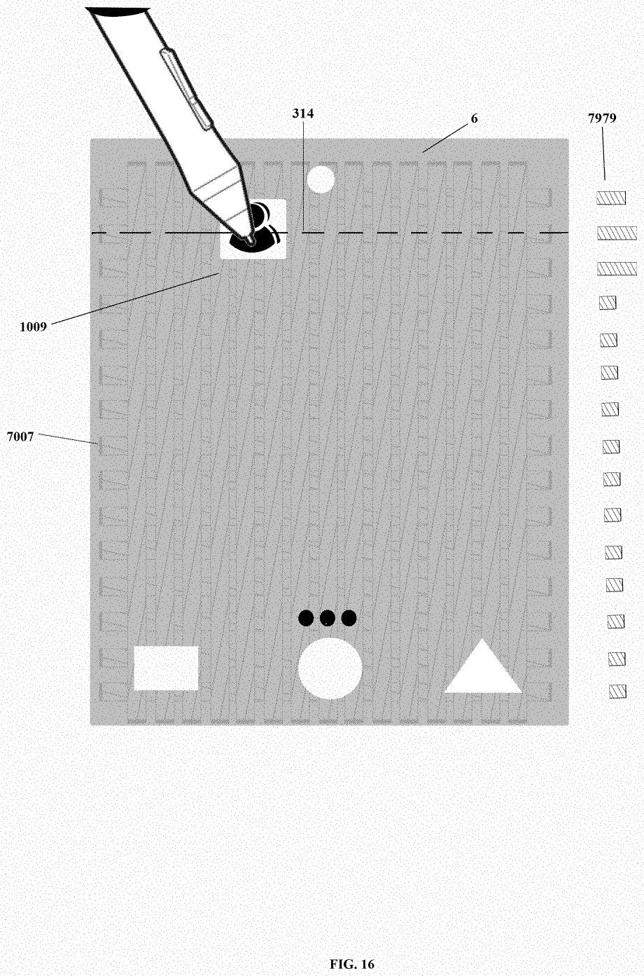

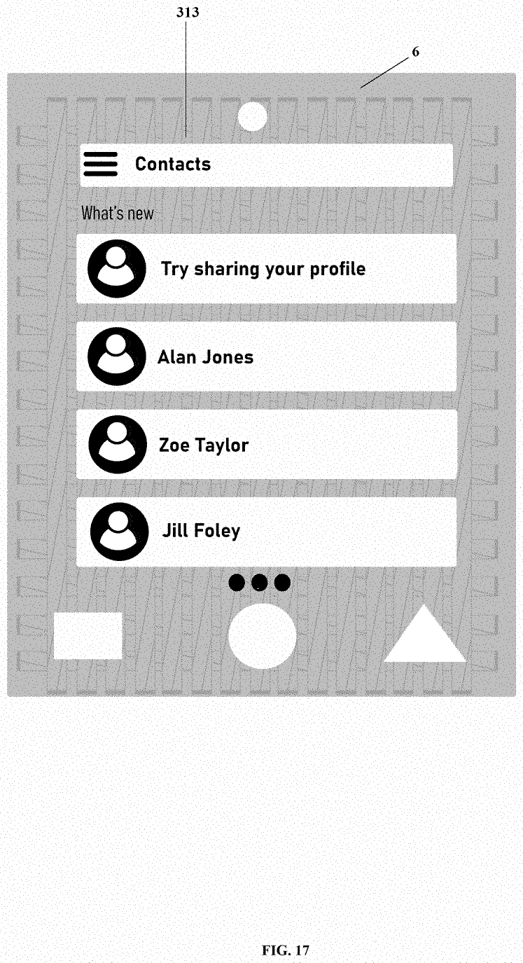

FIG. 14 is an illustration of an flow chart of the current concepts of the invention. While FIGS. 15-17 is conceptual views showing embodiment(s) of the flow chart of FIG. 14. As described above, the terminal 1001 consist of an touch panel sensor 7007 in conjunction with the geographical user interface 310 of the display 6 for executing an function of the one or more object(s) 1009 based upon the user interaction with the one or more object(s) 1009 according to an embodiment of the present invention. As shown, the terminal 1001 consist of one or more object(s) 1009 disposed intermediate the first row(s) geographical area 7024, second row(s) geographical area 7026, third row(s) geographical area 7028, fourth row(s) geographical area 7030, fifth row(s) geographical area 7032, first column(s) geographical area 7025, second column(s) geographical area 7027, third column(s) geographical area 7029, fourth column(s) geographical area 7031 and fifth column(s) geographical area 7033. The one or more object(s) 1009 can be aligned on the display 6 in an stacked formation at an vertical and horizontal arrangement, but is not limited to any other formation.

Further, the one or more processor(s) 7 is configured to generate an execution opening region 314 at an upper area of the display 6. Specifically, in conjunction with the display 6 and touch panel sensor 7007 the execution opening region 314 is generated on the display 6 at an middle area of the subset(s) of the first row(s) geographical area 7024 of the display 6 upon the user interaction (e.g., pressing and moving the object(s) 1009 towards the subset(s) of the first row(s) geographical area 7024, and the input circuitry 7009 measuring the row(s) signal 9797 determining that the first row(s) geographical area 7024 has an higher relative signal strength (e.g., threshold) than the second row(s) geographical area 7026 (9030). Furthermore, the functions of the object(s) 1009 are displayed on an second user interface 313 of the display 6 based upon the user interaction (e.g., pressing and moving the object(s) 1009 towards the middle area of the subset(s) of the first row(s) geographical area 7024 and the input circuitry 7009 measuring the row(s) signal(s)) 9797 of the row(s) and determining that the first row(s) geographical area 7024 has an higher relative signal strength (e.g., threshold) than the prior row(s) signal(s) 9797 obtained via the user adjusting the object(s) 1009 toward(s) the middle area of the subset(s) of the first row(s) geographical area 7024 (9031).

As described above, the method according to the exemplary embodiments of the present invention may be implemented by computer-readable codes in a program-recorded medium. The computer readable medium includes any kind of recording device in which data that can be read by a computer system is stored. The computer-readable medium may include a ROM, a RAM, a CD-ROM, a magnetic tape, a floppy disk, an optical data storage device, and the like. The computer-readable medium also includes implementations in the form of carrier waves or signals (e.g., transmission via the Internet). In addition, the computer may include the one or more processor(s) 7 of the terminal 1001.

As so far described, according to the exemplary embodiments of the present invention, the functions of the object(s) 1009 are implemented to be opened in a second user interface 313, and the terminal 1001 can display and operate the functions of the object(s) 1009. As the exemplary embodiments may be implemented in several forms without departing from the characteristics thereof, it should also be understood that the above-described embodiments are not limited by any of the details of the foregoing description, unless otherwise specified, but rather should be construed broadly within its scope as defined in the appended claims. Therefore, various changes and modifications that fall within the scope of the claims, are therefore intended to be embraced by the appended claims.

Having described my invention, I claim:

1. A terminal comprising:
a wrist sleeve portion having a exterior layer at a non-contact position of a user wrist and a interior layer at a contact position of the user wrist; and wherein the exterior layer of the non-contact position and interior layer of the contact position constitutes a stacked layer having respective layers coupled to the exterior layer of the non-contact position and interior layer of the contact position; and wherein each of the respective layers coupled to the exterior layer of the non-contact and interior layer of the contact position is made of a material having a predetermine thickness; wherein the exterior layer of the non-contact position consist of a inner layer coupled to the exterior layer, a intermediate layer coupled to the inner layer, a structuring layer coupled to the intermediate layer; and wherein the interior layer of the contact position consist of the intermediate layer coupled to the interior layer, and a inner layer coupled to the intermediate layer; and
a flexible display assembly disposed on a top surface of the wrist sleeve portion configured to display a object; and wherein the flexible display assembly constitutes the stacked layer having one or more layers made of the material having the predetermine thickness; and wherein the flexible display assembly is formed of a display coupled to a rear cover layer, a second display protective layer coupled to the display, a first display protective layer coupled to the second display protective layer, a flexible plastic film layer coupled to the second display protective layer and the flexible plastic film layer coupled to the flexible window housing; and
whereas the intermediate layer coupled to the inner layer of the non-contact position comprises a thin flexible keymat coupled to a body of the intermediate layer, wherein the flexible keymat coupled of the inner layer of the non-contact position comprises a top and rear side, wherein the flexible keymat comprises a recessed at each key position, wherein a slight bulge is firmed on a bottom side of the recessed at each key position, wherein a slight bulge is formed on a bottom side of the recessed at the rear side of the flexible keymat of each key location; and whereas the top side of the flexible keymat comprises a upward projecting lip at a rim of each key location of the recesses; and
wherein the flexible keymat comprises a keytop at each key location, wherein the keytops comprises a circling recessed configured to assemble on top the upward projecting lip of each key location; and wherein a trim member is disposed around the keytops coupled to the exterior layer of the non-contact position;
wherein the wrist sleeve portion comprises a keydom layer disposed intermediate the keymat and a second flexible printed circuit configured to distribute a signal to the second flexible printed circuit based upon a user pressing a keytop.

2. The terminal of claim 1, whereas the exterior layer of the non-contact position comprises thickness in range of 0.5 mm and up, whereas the exterior layer of the non-contact position is made up of fibers, nylon, polyester, cotton, leather, flexible plastic or a combination thereof; and the intermediate layer of the non-contact position comprises thickness in range of 0.3 mm and up, whereas the intermediate layer of the non-contact position is made up of a cellulose, viscose rayon, synthetic shammy material or a combination thereof; and whereas the inner layer of the non-contact position comprises thickness in range of 0.2 mm and up, whereas the inner layer of the non-contact position is made up of flexible rubber material; whereas the interior layer of the contact position comprises thickness in range of 0.5 mm and up, whereas the interior layer of the contact position is made up of fibers, nylon, polyester, cotton, leather, flexible plastic or a combination thereof; the intermediate layer of the contact position comprises thickness in range of 0.3 mm and up, whereas the intermediate layer of the non-contact position is made up of a cellulose, viscose rayon, synthetic shammy material or a combination thereof; and whereas the inner layer of the contact position comprises thickness in range of 0.2 mm and up, whereas the inner layer of the non-contact position is made up of flexible rubber material; and whereas the structuring layer of the contact position comprises thickness in range of 0.3 mm and up, whereas the inner layer of the non-contact position is made up of flexible rubber material.

3. The terminal of claim 1, whereas the flexible widow housing comprises thickness inner layer in range of 1.27 mm and up, whereas the flexible window housing is made of silicone rubber, leather or flexible plastic material; and whereas the rear cover layer comprises thickness in range of 3.35 mm and up, whereas the rear cove layer is made of flexible rubber material; and whereas the first display protective layer comprises thickness inner layer in range of 0.01 mm and up, whereas the first display protective layer is made of a thin flexible transparent material; and whereas the second display protective layer comprises thickness in range of 0.05 mm and up, whereas the second display protective layer is made of thin flexible transparent material; and whereas the flexible plastic film layer comprises thickness in range of 0.05 mm and up, whereas the flexible plastic film layer is made of thin flexible transparent material.

4. The terminal of claim 1, further comprising one or more adhesive layers made of thermoplastic material disposed on a top side of the structuring layer coupled to the intermediate layer of the non-contact position.

5. The terminal of claim 1, further comprising a flap assembly is coupled to the display assembly.

6. The terminal of claim 1, further comprising a flap assembly is coupled to the display assembly via a intermediate segment.

7. A terminal comprising:
a display, wherein the display comprises an touch panel sensor communicable coupled to the display, wherein the touch panel sensor of the display consist of one or more row(s) and column(s) for sensing a change in capacitance based upon an user interaction over the display, and wherein the one or more row(s) and column(s) of the touch panel sensor is respectively bifurcated into a subset of the row(s) and column(s);
a processor communicable coupled to a touch panel controller, wherein the processor is configured generate and display an execution opening region at a upper area of the display midway a first row(s) geographical area, and wherein the execution opening region is displayed at the upper area of the display based upon the user pressing and moving a object from a first location towards the first column geographical area in conjunction with a input circuitry sensing a change in capacitance determining that the first row(s) geographical area has an higher relative signal strength than a second row(s) geographical area, and wherein a function(s) of the object is executed on a second user interface of the display based upon the user pressing and moving the object from the first location toward the upper area of the display and the input circuitry sensing a change in capacitance determining that the first row(s) geographical area has an higher relative signal strength than a prior row signal obtained based upon the user adjusting the object toward the middle area of the subset(s) of the first row(s) geographical area.

8. The terminal of claim 7, wherein the object is a icon.

9. The terminal of claim 7, wherein the execution opening region consists of a horizontal dashed line.

10. A method for displaying and executing a function of an object on a display, the method comprising the steps of:
generating, by the processor, an execution opening region at a upper area of the display midway a first row(s) geographical area, and wherein the execution opening region is displayed at a upper area of the display based upon the user pressing and moving a object from a first location towards the first column geographical area in conjunction with a input circuitry sensing a change in capacitance determining that the first row(s) geographical area has an higher relative signal strength than a second row(s) geographical area; and
generating, by the display, a function(s) of the object on a second user interface of the display based upon the user pressing and moving the object from the first location toward the upper area of the display and the input circuitry sensing a change in capacitance determining that the first row(s) geographical area has an higher relative signal strength than a prior row signal obtained based upon the user adjusting the object toward the middle area of the subset(s) of the first row(s) geographical area.

11. The method of claim 10, wherein the object is a icon.

12. The method of claim 10, wherein the execution opening region consists of a horizontal dashed line.
